(19) United States
(12) Patent Application Publication
(10) Pub. No.: US 2026/0074654 A1
(43) Pub. Date: Mar. 12, 2026

(54) CIRCUIT DEVICE AND OSCILLATOR

(71) Applicant: SEIKO EPSON CORPORATION, Tokyo (JP)

(72) Inventor: Hanamichi Tanaka, Minowa-machi (JP)

(21) Appl. No.: 19/324,649

(22) Filed: Sep. 10, 2025

(30) Foreign Application Priority Data
Sep. 11, 2024 (JP) 2024-157329

(51) Int. Cl. H03B 5/04; H03B 5/30

(52) U.S. Cl. CPC H03B 5/04; H03B 5/30

(57) ABSTRACT

A circuit device that operates by being supplied with a power supply voltage includes an oscillation circuit configured to oscillate a resonator; a temperature sensor configured to output a temperature detection voltage; an offset adjustment circuit configured to output an offset adjustment voltage of the temperature detection voltage; a correction voltage output circuit configured to receive inputs of the power supply voltage and the offset adjustment voltage and output a correction voltage that changes in accordance with the power supply voltage and the offset adjustment voltage; a correction circuit configured to receive inputs of the temperature detection voltage and the correction voltage and output a temperature detection voltage corrected with the correction voltage; and a temperature compensation circuit configured to perform temperature compensation of an oscillation frequency of the oscillation circuit based on the corrected temperature detection voltage.

The present application is based on, and claims priority from JP Application Serial Number 2024-157329, filed Sep. 11, 2024, the disclosure of which is hereby incorporated by reference herein in its entirety.

### BACKGROUND

### 1. Technical Field

The present disclosure relates to a circuit device, an oscillator, and the like.

### 2. Related Art

Temperature compensation of an oscillation frequency is performed in a circuit device that oscillates a resonator such as a quartz crystal resonator. For example, JP-A-2023-090099 discloses an oscillator including a correction circuit that performs correction to change a temperature compensation voltage in accordance with a variation in power supply voltage. Furthermore, JP-A-2023-090099 discloses that a temperature sensor is provided with a variable resistor, and a resistance value of the variable resistor is changed to adjust an offset of a temperature detection voltage, thereby performing temperature compensation of a zero-order component or the like of frequency-temperature characteristics of a resonator.

However, a temperature compensation circuit system that appropriately reflects influences of the variation in power supply voltage and the offset adjustment has not been proposed.

### SUMMARY

An aspect of the present disclosure relates to a circuit device that operates by being supplied with a power supply voltage, including an oscillation circuit configured to oscillate a resonator; a temperature sensor configured to output a temperature detection voltage; an offset adjustment circuit configured to output an offset adjustment voltage of the temperature detection voltage; a correction voltage output circuit configured to receive inputs of the power supply voltage and the offset adjustment voltage and output a correction voltage that changes in accordance with the power supply voltage and the offset adjustment voltage; a correction circuit configured to receive inputs of the temperature detection voltage and the correction voltage and output the temperature detection voltage corrected with the correction voltage; and a temperature compensation circuit configured to perform temperature compensation of an oscillation frequency of the oscillation circuit based on the corrected temperature detection voltage.

Also, another aspect of the present disclosure relates to an oscillator including the circuit device described above; and the resonator.

### BRIEF DESCRIPTION OF THE DRAWINGS

FIG. 1 is a configuration example of a circuit device and an oscillator of the present embodiment.

FIG. 2 is a detailed configuration example of the circuit device and the oscillator of the present embodiment.

FIG. 3 is an example of frequency-temperature characteristics when a power supply voltage rises.

FIG. 4 is an example of frequency-temperature characteristics when the power supply voltage drops.

FIG. 5 is a configuration example of an offset adjustment circuit, a correction voltage output circuit, and a correction circuit.

FIG. 6 is a detailed configuration example of the correction voltage output circuit that makes a resistance ratio or the like variable.

FIG. 7 is an explanatory diagram of a method of generating a correction voltage in accordance with the power supply voltage.

FIG. 8 is an example of temperature characteristics of a temperature detection voltage.

FIG. 9 is an explanatory diagram of a correction method of the present embodiment.

FIG. 10 is a configuration example of a temperature compensation circuit.

FIG. 11 is a first configuration example of a temperature sensor.

FIG. 12 is a second configuration example of the temperature sensor.

FIG. 13 is a configuration example of a temperature sensor of a comparative example.

FIG. 14 is a configuration example of a correction circuit of the comparative example.

FIG. 15 is an explanatory diagram of a problem of a change in gradient characteristics of a temperature detection voltage in the comparative example.

FIG. 16 is an explanatory diagram of linearity of an offset adjustment voltage in the comparative example.

FIG. 17 is an explanatory diagram of linearity of an offset adjustment voltage in the present embodiment.

FIG. 18 is an explanatory diagram of a change in inflection point temperature due to offset adjustment.

FIG. 19 is a first structure example of an oscillator.

FIG. 20 is a second structure example of the oscillator.

### DESCRIPTION OF EMBODIMENTS

The present embodiment will be described below. Note that the present embodiment described below does not unduly limit the scope of the claims. In addition, not all of the configurations described in the present embodiment are necessarily essential configuration requirements.

### 1. Circuit Device

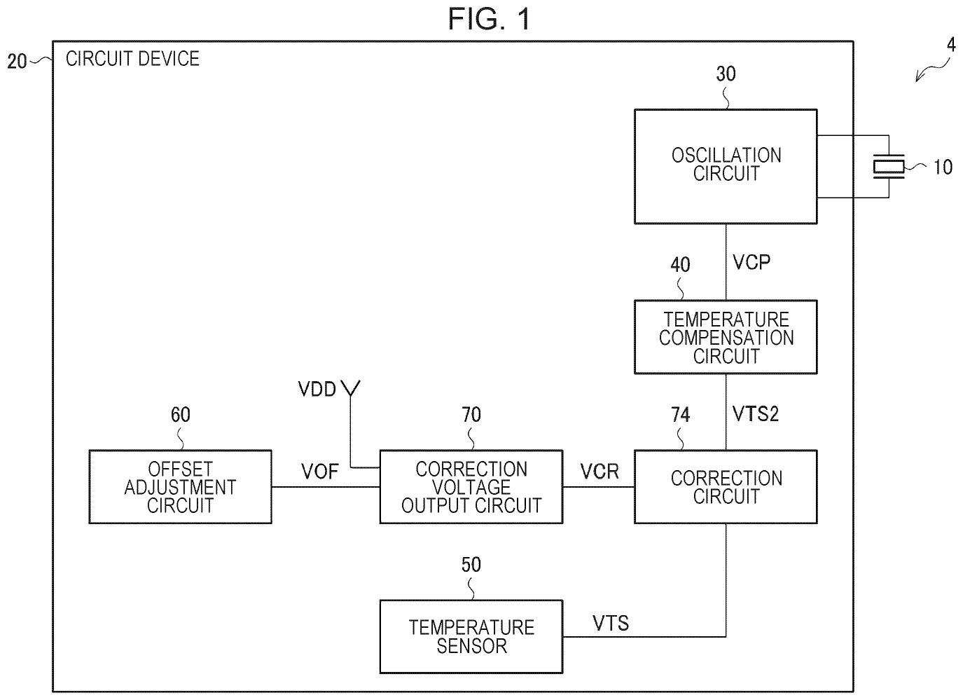

FIG. 1 illustrates a configuration example of a circuit device 20 of the present embodiment. The circuit device 20 of the present embodiment includes an oscillation circuit 30, a temperature compensation circuit 40, a temperature sensor 50, an offset adjustment circuit 60, a correction voltage output circuit 70, and a correction circuit 74. An oscillator 4 of the present embodiment includes a resonator 10 and the circuit device 20. The resonator 10 is electrically connected to the circuit device 20. Note that the circuit device 20 and the oscillator 4 are not limited to the configuration in FIG. 1, and various modifications such as omitting some of the components, adding other components, or replacing some of the components with other components can be made.

The resonator 10 is an element that generates mechanical vibration by an electrical signal. The resonator 10 can be realized by a resonator element such as a quartz crystal resonator element, for example. For example, the resonator 10 can be realized by a quartz crystal resonator element that has a cut angle such as an AT cut or an SC cut and thickness-shear vibrates, a tuning fork type quartz crystal resonator element, a double tuning fork type quartz crystal resonator element, or the like. For example, the resonator 10 may be a resonator built in a temperature compensated crystal oscillator (TCXO) which does not include a thermostatic oven or may be a resonator built in an oven controlled crystal oscillator (OCXO) which includes a thermostatic oven. Note that the resonator 10 of the present embodiment can also be realized by various resonator elements such as a resonator element other than the thickness-shear vibration type, the tuning fork type, and the double tuning fork type, for example, or a piezoelectric resonator element formed of a material other than quartz crystal. For example, a surface acoustic wave (SAW) resonator, a micro electro mechanical systems (MEMS) resonator as a silicon resonator formed by using a silicon substrate, or the like can also be adopted as the resonator 10.

The circuit device 20 is an integrated circuit device called an integrated circuit (IC). For example, the circuit device 20 is an IC manufactured by a semiconductor process, and is a semiconductor chip in which a circuit element is formed on a semiconductor substrate. The circuit device 20 operates based on a power supply voltage VDD.

The oscillation circuit 30 is a circuit that oscillates the resonator 10. For example, the oscillation circuit 30 generates an oscillation signal by oscillating the resonator 10. The oscillation signal is an oscillation clock signal. For example, the oscillation circuit 30 can be realized by a drive circuit for oscillation electrically connected to one end and the other end of the resonator 10 and a passive element such as a capacitor or a resistor. The drive circuit can be realized by, for example, a CMOS inverter circuit or a bipolar transistor. The drive circuit is a core circuit of the oscillation circuit 30, and the drive circuit causes the resonator 10 to oscillate by voltage-driving or current-driving the resonator 10. As the oscillation circuit 30, various types of oscillation circuits such as an inverter type, a Pierce type, a Colpitts type, and a Hartley type, for example, can be used. Note that the connection in the present embodiment is electrical connection. The electrical connection is connection through which an electrical signal is transmissible, and is connection through which information is transmissible by an electrical signal. The electrical connection may be connection via a passive element or the like.

The temperature sensor 50 is a sensor that detects a temperature. Specifically, the temperature sensor 50 outputs, as a temperature detection voltage VTS, a temperature-dependent voltage that changes in accordance with an environmental temperature. For example, the temperature sensor 50 generates the temperature detection voltage VTS which is a temperature detection signal by using a circuit element having temperature dependency.

Specifically, the temperature sensor 50 outputs the temperature detection voltage VTS that changes depending on the temperature by using, for example, temperature dependency that a forward voltage of a PN junction has. Note that a modification in which a digital temperature sensor circuit is used as the temperature sensor 50 is also possible. In this case, the temperature detection voltage VTS may be generated by D/A converting temperature detection data.

The offset adjustment circuit 60 outputs an offset adjustment voltage VOF. The offset adjustment voltage VOF is, for example, a voltage for offset adjustment of the temperature detection voltage VTS. The offset adjustment can also be referred to as zero-order offset adjustment. For example, the offset adjustment circuit 60 generates the offset adjustment voltage VOF based on zero-order correction data corresponding to a zero-order coefficient of a polynomial in polynomial approximation of temperature compensation characteristics. In this manner, the temperature detection voltage VTS is offset-adjusted by the amount of an offset indicated by the zero-order correction data, and is input to the temperature compensation circuit 40 as a corrected temperature detection voltage VTS2. It is thus possible to adjust an offset variation of the temperature detection voltage VTS due to a manufacturing variation or the like.

The correction voltage output circuit 70 outputs a correction voltage VCR. For example, the correction voltage output circuit 70 receives inputs of the power supply voltage VDD and the offset adjustment voltage VOF and outputs the correction voltage VCR that changes in accordance with the power supply voltage VDD and the offset adjustment voltage VOF. For example, the correction voltage VCR is a voltage that changes by a voltage corresponding to a change in power supply voltage VDD and changes by a voltage corresponding to a change in the offset adjustment voltage VOF. For example, the correction voltage VCR is a subtraction voltage or an addition voltage of a voltage obtained by multiplying the offset adjustment voltage VOF by a given coefficient and a voltage obtained by multiplying the power supply voltage VDD by a given coefficient. In one example, the correction voltage VCR decreases when the power supply voltage VDD increases, and increases when the offset adjustment voltage VOF increases. In this manner, the correction voltage output circuit 70 outputs the correction voltage VCR that reflects the changes in both the voltages, namely the power supply voltage VDD and the offset adjustment voltage VOF.

The correction circuit 74 outputs a corrected temperature detection voltage VTS2. For example, the correction circuit 74 receives inputs of the temperature detection voltage VTS and the correction voltage VCR and outputs the temperature detection voltage VTS2 corrected with the correction voltage VCR. The corrected temperature detection voltage VTS2 is, for example, a voltage obtained by changing the temperature detection voltage VTS by a voltage corresponding to the correction voltage VCR. For example, the corrected temperature detection voltage VTS2 is a subtraction voltage or an addition voltage of a voltage obtained by multiplying the temperature detection voltage VTS by a given coefficient and a voltage obtained by multiplying the correction voltage VCR by a given coefficient. In one example, the corrected temperature detection voltage VTS2 increases when the temperature detection voltage VTS increases, and decreases when the correction voltage VCR increases. In this manner, the correction circuit 74 outputs the temperature detection voltage VTS2 obtained by correcting the temperature detection voltage VTS with the correction voltage VCR obtained based on the power supply voltage VDD and the offset adjustment voltage VOF. In this manner, the temperature detection voltage VTS2 that reflects changes in power supply voltage VDD and offset adjustment voltage VOF on the temperature detection voltage VTS from the temperature sensor 50 is generated. Note that a modification in which the correction circuit 74 corrects the temperature detection voltage VTS from the temperature sensor 50 provided outside the circuit device 20 and outputs the temperature detection voltage VTS2 is also possible.

The temperature compensation circuit 40 performs temperature compensation of an oscillation frequency of the oscillation circuit 30. The temperature compensation is, for example, processing of suppressing and compensating for a variation in oscillation frequency due to a variation in temperature. In other words, the temperature compensation circuit 40 performs temperature compensation of the oscillation frequency of the oscillation circuit 30 such that the oscillation frequency is kept constant even in a case where there is a variation in temperature. In the present embodiment, the temperature compensation circuit 40 performs temperature compensation of the oscillation frequency of the oscillation circuit 30 based on the corrected temperature detection voltage VTS2. For example, the temperature compensation circuit 40 outputs a temperature compensation voltage VCP for temperature-compensating the oscillation frequency based on the temperature detection voltage VTS2. In this manner, the temperature compensation circuit 40 performs temperature compensation of the oscillation frequency of the oscillation circuit 30 based on the temperature detection voltage VTS2 obtained by correcting the temperature detection voltage VTS of the temperature sensor 50 with the correction voltage VCR obtained based on the power supply voltage VDD and the offset adjustment voltage VOF. Note that a modification in which the oscillation frequency is digitally adjusted in a variable capacitance circuit of the oscillation circuit 30 using temperature compensation data obtained by A/D converting the temperature compensation voltage VCP is also possible.

For example, if the power supply voltage VDD rises, then the amount of heat generation of the circuit device 20 which operates by being supplied with the power supply voltage VDD increases, and the temperature detected by the temperature sensor 50 rises. However, since the circuit device 20 and the resonator 10 are disposed at positions physically separated from each other, the detected temperature at the circuit device 20 and the temperature of the resonator 10 do not coincide with each other, and for example, the temperature of the resonator 10 is lower. Therefore, if the temperature compensation circuit 40 outputs the temperature compensation voltage VCP based on the temperature detection voltage VTS of the temperature sensor 50 of the circuit device 20, and the temperature compensation of the oscillation frequency of the resonator 10 is performed with the temperature compensation voltage VCP, then a situation in which accurate temperature compensation cannot be realized occurs.

Furthermore, it is necessary to perform zero-order offset adjustment in the temperature compensation of the oscillation frequency. The zero-order offset adjustment can be realized by, for example, offset adjustment of the temperature detection voltage VTS. In this regard, in the related art of JP-A-2023-090099 described above, the temperature sensor 50 is provided with a variable resistor, and the resistance value of the variable resistor is adjusted to thereby perform offset adjustment of the temperature detection voltage VTS in the temperature sensor 50. However, as will be described in detail later, it has been found that the method of the related art has a problem that linearity of the offset adjustment is degraded or gradient characteristics of the temperature detection voltage VTS with respect to the temperature are changed due to the offset adjustment.

Thus, the temperature sensor 50 is not provided with an offset adjustment function of the temperature detection voltage VTS, and the offset adjustment circuit 60 that outputs the offset adjustment voltage VOF is provided separately from the temperature sensor 50 in the present embodiment. Furthermore, the correction voltage output circuit 70 outputs the correction voltage VCR that changes in accordance with the power supply voltage VDD and the offset adjustment voltage VOF, and the correction circuit 74 outputs the temperature detection voltage VTS2 obtained by correcting the temperature detection voltage VTS of the temperature sensor 50 with the correction voltage VCR. Then, the temperature compensation circuit 40 performs the temperature compensation of the oscillation frequency of the oscillation circuit 30 based on the temperature detection voltage VTS2 corrected by the correction circuit 74. For example, the temperature compensation of the oscillation frequency is performed by the capacitance of the variable capacitance circuit provided in the oscillation circuit 30 being adjusted based on the temperature compensation voltage VCP from the temperature compensation circuit 40.

In this manner, even in a case of a situation where the temperature difference between the detected temperature at the circuit device 20 and the temperature of the resonator 10 increases due to a variation in the power supply voltage VDD and an error occurs in the temperature compensation, it is possible to achieve an improvement or the like in the accuracy of the oscillation frequency by performing correction to reduce the error.

In the present embodiment, the offset adjustment circuit 60 is provided separately from the temperature sensor 50 to generate the offset adjustment voltage VOF, the temperature detection voltage VTS of the temperature sensor 50 is corrected with the correction voltage VCR generated from the power supply voltage VDD and the offset adjustment voltage VOF, and the temperature compensation is performed with the corrected temperature detection voltage VTS2. Therefore, it is possible to suppress the problem of the degradation of the linearity of the offset adjustment caused by providing the temperature sensor 50 with the offset adjustment function and the problem that the gradient characteristics of the temperature detection voltage VTS are changed due to the offset adjustment. In addition, since temperature compensation is performed with the temperature detection voltage VTS corrected with the correction voltage VCR based on the power supply voltage VDD and the offset adjustment voltage VOF, it is also possible to perform correction in a high-order circuit of the temperature compensation circuit 40, and it is possible to realize appropriate temperature compensation of the oscillation frequency.

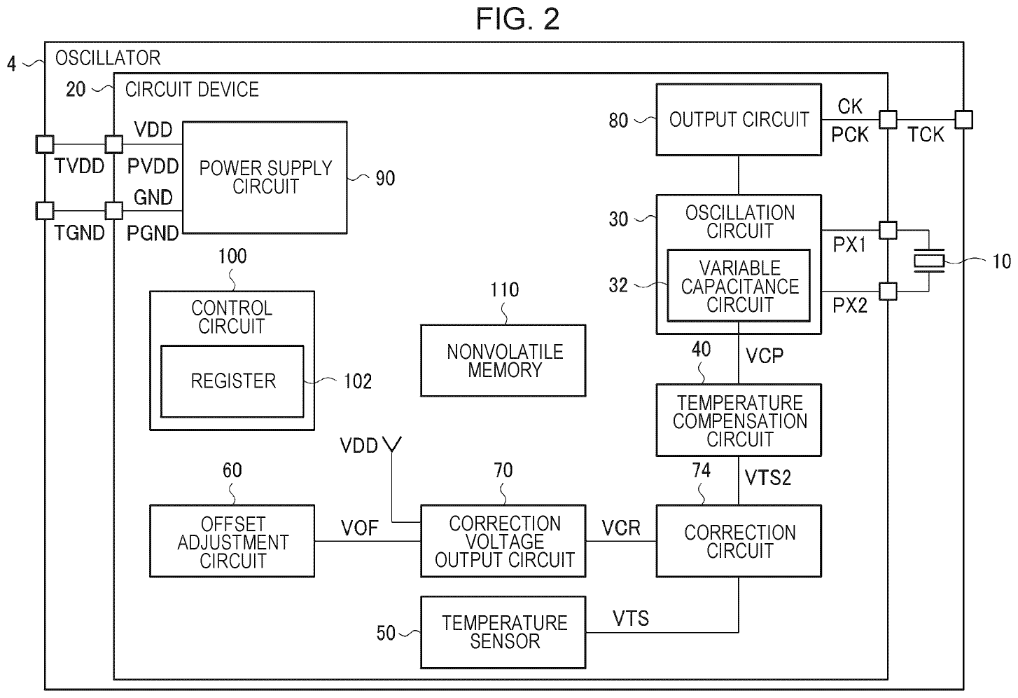

FIG. 2 illustrates a detailed configuration example of the circuit device 20 and the oscillator 4 of the present embodiment. In FIG. 2, the circuit device 20 includes an output circuit 80, a power supply circuit 90, a control circuit 100, and a nonvolatile memory 110 in addition to the oscillation circuit 30, the temperature compensation circuit 40, the temperature sensor 50, the offset adjustment circuit 60, the correction voltage output circuit 70, and the correction circuit 74. Furthermore, the oscillator 4 includes the resonator 10 and the circuit device 20, and the resonator 10 is electrically connected to the circuit device 20. For example, the resonator 10 and the circuit device 20 are electrically connected to each other by using internal wiring, a bonding wire, a metal bump, or the like of a package that accommodates the resonator 10 and the circuit device 20. Note that the circuit device 20 and the oscillator 4 are not limited to the configurations in FIG. 2, and various modifications such as omitting some of the components, adding other components, or replacing some of the components with other components can be made.

Also, the circuit device 20 includes pads PVDD, PGND, PX1, PX2, and PCK. The pads are terminals of the circuit device 20 which is a semiconductor chip. For example, a metal layer is exposed from a passivation film which is an insulating layer in pad regions, and the exposed metal layer configures the pads, which are the terminals of the circuit device 20. The pads PVDD and PGND are a power supply pad and a ground pad, respectively. The power supply voltage VDD from an external power supply device is supplied to the pad PVDD. The pad PGND is a pad to which GND that is a ground voltage is supplied. GND can also be referred to as VSS, and the ground voltage is, for example, a ground potential. In the present embodiment, the ground will be described as GND as appropriate. For example, VDD corresponds to a high-potential-side power supply, and GND corresponds to a low-potential-side power supply. The pads PX1 and PX2 are connection pads for the resonator 10. The pad PCK is a pad for outputting a clock signal CK. The pads PVDD, PGND, and PCK are electrically connected to terminals TVDD, TGND, and TCK which are external terminals for external connection of the oscillator 4, respectively. For example, each of the pads and the terminals is electrically connected to each other using internal wiring, a bonding wire, a metal bump, or the like of the package. Note that a terminal and a pad to which a control voltage from the outside is input may be provided such that an external system can control the oscillation frequency with the control voltage.

The oscillation circuit 30 is electrically connected to the resonator 10 via the pads PX1 and PX2. The pads PX1 and PX2 are pads for connecting the resonator. A drive circuit for oscillation of the oscillation circuit 30 is provided between the pad PX1 and the pad PX2. The oscillation circuit 30 includes a variable capacitance circuit 32. The variable capacitance circuit 32 is, for example, a circuit that changes the capacitance of at least one of one end and the other end of the resonator 10, and the oscillation frequency of the oscillation circuit 30 can be adjusted by adjusting the capacitance of the variable capacitance circuit 32. In other words, the load capacitance of the oscillation circuit 30 can be variably adjusted by the variable capacitance circuit 32 being electrically connected to at least one of the pads PX1 and PX2. The variable capacitance circuit 32 can be realized by, for example, a variable capacitance element such as a varactor. For example, the variable capacitance circuit 32 is configured of at least one variable capacitance element.

The temperature compensation circuit 40 performs, for example, analog temperature compensation by polynomial approximation. For example, in a case where the temperature compensation voltage VCP for compensating the frequency-temperature characteristics of the resonator 10 is approximated by a polynomial, the temperature compensation circuit 40 performs the analog temperature compensation based on coefficient information of the polynomial. The analog temperature compensation is temperature compensation realized by, for example, addition processing of a current signal or a voltage signal which is an analog signal. For example, in a case where the temperature compensation voltage VCP is approximated by a high-order polynomial, a zero-order coefficient, a first-order coefficient, and a high-order coefficient of the polynomial are stored as zero-order correction data, first-order correction data, and high-order correction data, respectively, in a storage section which is realized by, for example, the nonvolatile memory 110. The high-order coefficient is, for example, a coefficient of an order higher than the first order, and the high-order correction data is correction data corresponding to the high-order coefficient. For example, in a case where the temperature compensation voltage VCP is approximated by a third-order polynomial, a zero-order coefficient, a first-order coefficient, a second-order coefficient, and a third-order coefficient of the polynomial are stored in the storage section as zero-order correction data, first-order correction data, second-order correction data, and third-order correction data. Then, the temperature compensation circuit 40 performs temperature compensation based on the zero-order correction data to the third-order correction data. In this case, the second-order correction data and the temperature compensation based on the second-order correction data may be omitted. For example, in a case where the temperature compensation voltage VCP is approximated by a fifth-order polynomial, a zero-order coefficient, a first-order coefficient, a second-order coefficient, a third-order coefficient, a fourth-order coefficient, and a fifth-order coefficient of the polynomial are stored in the storage section as zero-order correction data, first-order correction data, second-order correction data, third-order correction data, fourth-order correction data, and fifth-order correction data. Then, the temperature compensation circuit 40 performs temperature compensation based on the zero-order correction data to the fifth-order correction data. In this case, the second-order correction data or the fourth-order correction data, and the temperature compensation based on the second-order correction data or the fourth-order correction data may be omitted.

Furthermore, the order of the polynomial approximation is selected as needed, and for example, polynomial approximation of an order higher than the fifth order may be performed.

The control circuit 100 is a circuit that performs various kinds of control processing, and is realized by, for example, a logic circuit or the like. For example, the control circuit 100 performs entire control of the circuit device 20 and controls an operation sequence of the circuit device 20. In addition, the control circuit 100 performs various kinds of processing for controlling the oscillation circuit 30, controls the temperature compensation circuit 40, the temperature sensor 50, the offset adjustment circuit 60, the correction voltage output circuit 70, the correction circuit 74, the output circuit 80, or the power supply circuit 90, and controls reading and writing of information in the nonvolatile memory 110. The control circuit 100 can be realized by, for example, an application specific integrated circuit (ASIC) by automatic arrangement and routing such as a gate array. Also, the control circuit 100 includes a register 102. For example, the register 102 is realized by a storage circuit such as a flip-flop circuit. The register 102 stores various kinds of information necessary for the temperature compensation processing and the correction processing. For example, the control circuit 100 performs various kinds of control processing based on the information read from the nonvolatile memory 110 and loaded into the register 102.

The nonvolatile memory 110 is a memory that holds stored information even when power is not supplied. For example, the nonvolatile memory 110 is a memory that can hold information without being supplied with power and allows information to be rewritten. The nonvolatile memory 110 stores various kinds of information necessary for the operation and the like of the circuit device 20. The nonvolatile memory 110 can be realized by an electrically erasable programmable read-only memory (EEPROM) or the like realized by a floating gate avalanche injection MOS memory (FAMOS memory) or a metal-oxide-nitride-oxide-silicon memory (MONOS memory). The nonvolatile memory 110 stores correction data such as first-order correction data and high-order correction data to be used for the temperature compensation of the temperature compensation circuit 40.

The output circuit 80 outputs a clock signal CK based on an oscillation signal of the oscillation circuit 30. For example, the output circuit 80 buffers an oscillation signal which is an oscillation clock signal from the oscillation circuit 30, and outputs the buffered oscillation signal as the clock signal CK to the pad PCK. Then, the clock signal CK is output to the outside via the clock output terminal TCK of the oscillator 4. For example, the output circuit 80 outputs the clock signal CK in a single-ended CMOS signal format. Note that the output circuit 80 may output the clock signal CK in a signal format other than CMOS. Furthermore, a clock signal generation circuit such as a PLL circuit that generates the clock signal CK having a frequency obtained by multiplying the frequency of the oscillation signal may be provided in a subsequent stage of the oscillation circuit 30, and the output circuit 80 may buffer and output the clock signal CK generated by the clock signal generation circuit.

The power supply circuit 90 is supplied with the power supply voltage VDD from the pad PVDD and the ground voltage GND from the pad PGND, and supplies various power supply voltages for internal circuits of the circuit device 20 to the internal circuits. For example, the power supply circuit 90 supplies a regulated power supply voltage obtained by regulating the power supply voltage VDD to each circuit of the circuit device 20 such as the oscillation circuit 30.

The oscillation circuit 30 includes the variable capacitance circuit 32 in which capacitance change characteristics with respect to a capacitance control voltage are, for example, positive characteristics. The positive capacitance change characteristics are change characteristics in which the capacitance increases as the capacitance control voltage rises. Note that the capacitance change characteristics of the variable capacitance circuit 32 may be negative characteristics. Then, the temperature compensation circuit 40 supplies the temperature compensation voltage VCP as the capacitance control voltage to the variable capacitance circuit 32. Since the variable capacitance circuit 32 is a variable capacitance circuit having positive characteristics, the capacitance of the variable capacitance circuit 32 increases when the temperature compensation voltage VCP from the temperature compensation circuit 40 rises, and the capacitance of the variable capacitance circuit 32 decreases when the temperature compensation voltage VCP drops. If the temperature rises, for example, then the capacitance of the variable capacitance circuit 32 increases, and the oscillation frequency of the oscillation circuit 30 drops, by providing the oscillation circuit 30 with the variable capacitance circuit 32 with the positive characteristics to which the temperature compensation voltage VCP from the temperature compensation circuit 40 is supplied as the capacitance control voltage in this manner. Accordingly, in a case where the oscillation frequency of the resonator 10 rises in a high temperature region, for example, the capacitance of the variable capacitance circuit 32 increases, and it is thus possible to realize temperature compensation that cancels out the increase in oscillation frequency. In addition, it is also possible to use, for example, an amplification circuit of a class A operation as, for example, an output amplifier of the temperature compensation voltage VCP of the temperature compensation circuit 40 by providing the variable capacitance circuit 32 having the positive characteristics in the oscillation circuit 30, and it is possible to realize size reduction of the circuit. Note that the oscillation circuit 30 may be provided with a variable capacitance circuit, the capacitance of which is controlled by a frequency control voltage input from the outside, such that the oscillation frequency can be variably controlled with the frequency control voltage.

### 2. Offset Adjustment Circuit, Correction Voltage Output Circuit, and Correction Circuit

In recent years, heat capacity has been reduced with miniaturization of the oscillator 4, and even in the circuit device 20 that generates heat with the same amount of heat generation, the amount of temperature rise of the oscillator 4 has increased. This leads to an increase in temperature difference between the temperature of the circuit device 20 which is a heat generation source and the outside air temperature and also an increase in temperature difference between the temperature of the circuit device 20 and the temperature of the resonator 10. If the temperature difference between the circuit device 20 and the resonator 10 increases in this manner, then a difference between the characteristics of the temperature compensation voltage VCP generated based on the temperature detection voltage VTS of the temperature sensor 50 incorporated in the circuit device 20 and the frequency-temperature characteristics determined by the temperature of the resonator 10 increases, and an error of the temperature compensation increases.

For example, the frequency-temperature characteristics of the oscillator 4 include an error for each of the individuals due to manufacturing variations, influences of mounting, and the like of the circuit device 20 which is an IC and the resonator 10. For this reason, adjustment is performed by an adjustment process before shipment or an adjustment function of the circuit device 20 such that an optimal temperature compensation voltage VCP for absorbing these errors is generated. However, measures against surrounding environments occurring after shipment of the product have been insufficient. Although the circuit device 20 operates by being supplied with the power supply voltage VDD from the outside, for example, the variation in power supply voltage VDD is determined to be, for example, 3.3 V±10% as a product specification. If the power supply voltage VDD varies, the amount of heat generation of the circuit device 20 operating based on the power supply voltage VDD also varies, and if the power supply voltage VDD rises, the amount of heat generation of the circuit device 20 also increases. In this case, the amount of temperature rise of the oscillator 4 due to the amount of heat generation of the circuit device 20 also increases with size reduction of the package or the like of the oscillator 4 in which the circuit device 20 is mounted. Accordingly, the temperature difference between the circuit device 20 and the resonator 10 increases as described above, and an error of the temperature compensation increases.

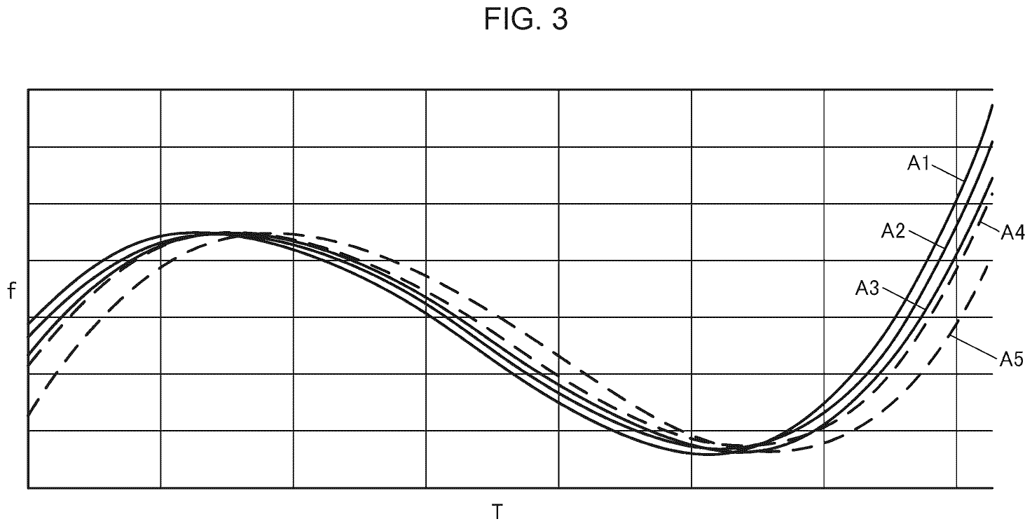

For example, FIG. 3 is an example of the frequency-temperature characteristics when the power supply voltage VDD rises. In FIG. 3, the horizontal axis represents a temperature T, and the vertical axis represents a frequency f which is an oscillation frequency. Although the vertical axis actually represents a frequency deviation with respect to the nominal frequency, the frequency deviation will be described below as the frequency f. In FIG. 3, A1 represents frequency-temperature characteristics of the resonator 10 in a case where the power supply voltage VDD is a typical voltage such as 3.3 V, for example. For example, adjustment is performed such that the temperature characteristics by the temperature compensation voltage VCP of the circuit device 20 and the frequency-temperature characteristics of the resonator 10 coincide with each other through an adjustment process or the like before shipment of the product. Specifically, since the temperature compensation is performed using the variable capacitance circuit 32 having positive characteristics in the circuit device 20 of FIG. 2, the capacitance of the variable capacitance circuit 32 increases and the oscillation frequency decreases if the temperature compensation voltage VCP rises, and the capacitance of the variable capacitance circuit 32 decreases and the oscillation frequency rises if the temperature compensation voltage VCP drops. Therefore, it is possible to cancel out the frequency-temperature characteristics of the resonator 10 by setting the frequency-temperature characteristics of the temperature compensation voltage VCP to the characteristics indicated by A1 in FIG. 3, and temperature compensation for keeping the oscillation frequency constant is realized.

In FIG. 3, A2 represents the frequency-temperature characteristics of the resonator 10 when VDD rises by +5%, and A3 represents the frequency-temperature characteristics of the resonator 10 when VDD rises by +10%. Although the temperature of the resonator 10 also rises due to, for example, the heat generation of the circuit device 20 caused by the rise of VDD, adequate temperature compensation through which the oscillation frequency is kept constant is realized by adjusting the temperature compensation voltage VCP to obtain the frequency-temperature characteristics as indicated by A2 and A3. Specifically, since the temperature compensation is performed using the variable capacitance circuit 32 having the positive characteristics in FIG. 2 as described above, it is possible to realize the temperature compensation to keep the oscillation frequency constant by setting the frequency-temperature characteristics of the temperature compensation voltage VCP to the characteristics as indicated by A2 and A3 in a case where the power supply voltage VDD varies.

However, the circuit device 20 performs the temperature compensation of the oscillation frequency by generating the temperature compensation voltage VCP based on the temperature detected by the built-in temperature sensor 50. As described above, there is a temperature difference between the circuit device 20 and the resonator 10, and in a case where the power supply voltage VDD rises and the amount of heat generation of the circuit device 20 increases as in FIG. 3, the temperature difference between the temperature detected by the temperature sensor 50 of the circuit device 20 and the temperature of the resonator 10 increases. For this reason, the circuit device 20 performs the temperature compensation using the temperature compensation voltage VCP having the frequency-temperature characteristics as indicated by A4 and A5 in FIG. 3, and a deviation from the frequency-temperature characteristics of A2 and A3 based on an actual temperature of the resonator 10 occurs. Therefore, an error occurs in the oscillation frequency after the temperature compensation, and the oscillation frequency cannot be accommodated within frequency accuracy of the specification.

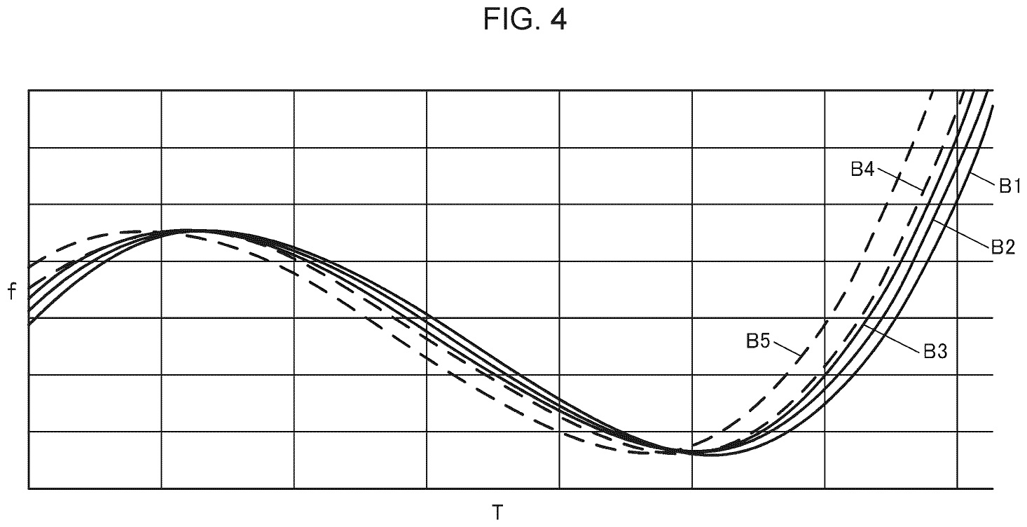

On the other hand, FIG. 4 is an example of the frequency-temperature characteristics when the power supply voltage VDD drops. In FIG. 4, B1 represents frequency-temperature characteristics of the resonator 10 in a case where the power supply voltage VDD is a typical voltage such as 3.3 V. In FIG. 4, B2 represents frequency-temperature characteristics of the resonator 10 when VDD drops by −5%, and B3 represents frequency-temperature characteristics of the resonator 10 when VDD drops by −10%. In this manner, even when the power supply voltage VDD drops, the circuit device 20 performs the temperature compensation with the temperature compensation voltage VCP having the frequency-temperature characteristics as indicated by B4 and B5 in FIG. 4 due to the temperature difference between the temperature detected by the temperature sensor 50 of the circuit device 20 and the temperature of the resonator 10, and a deviation from the frequency-temperature characteristics of B2 and B3 based on the actual temperature of the resonator 10 occurs. Therefore, an error occurs in the oscillation frequency after the temperature compensation, and the oscillation frequency cannot be accommodated within the frequency accuracy of the specification.

Furthermore, although it is necessary to perform zero-order offset adjustment in the temperature compensation, and in JP-A-2023-090099 described above, the zero-order offset adjustment is performed by the temperature sensor, it has been found that there is a problem that linearity of the offset adjustment may be degraded or gradient characteristics of the temperature detection voltage may change.

Thus, in the present embodiment, the offset adjustment circuit 60 generates the offset adjustment voltage VOF, the correction voltage output circuit 70 generates the correction voltage VCR based on the offset adjustment voltage VOF and the power supply voltage VDD, the correction circuit 74 corrects the temperature detection voltage VTS based on the correction voltage VCR, and the temperature compensation circuit 40 performs temperature compensation with the corrected temperature detection voltage VTS2. It is thus possible to realize the temperature compensation that appropriately reflects influences of the variation in power supply voltage VDD and the offset adjustment. FIG. 5 illustrates a configuration example of the offset adjustment circuit 60, the correction voltage output circuit 70, and the correction circuit 74. Note that the configurations of the offset adjustment circuit 60, the correction voltage output circuit 70, and the correction circuit 74 are not limited to the configurations in FIG. 5, and various modifications can be made.

In FIG. 5, a D/A conversion circuit of an R-2R ladder system is used as the offset adjustment circuit 60. For example, the offset adjustment circuit 60 is a circuit that performs D/A conversion on offset adjustment data into the offset adjustment voltage VOF by the R-2R ladder system. In other words, the zero-order offset adjustment function is realized by the R-2R ladder system. The offset adjustment data corresponds to, for example, zero-order correction data of the temperature compensation. In the R-2R ladder system, switches SW1 to SWm for switching VREG and GND corresponding to the number of bits of offset adjustment data are provided. Then, each of the switches SW1 to SWm is switched to the VREG side or the GND side based on each bit of the offset adjustment data to switch the resistance value, thereby generating the offset adjustment voltage VOF. Specifically, the offset adjustment circuit 60 includes resistors RA1 and RA2 provided in series between a power supply node of VREG and a GND node, the switches SW1 to SWm, a resistor having a resistance value 2R and provided between the nodes N1 to Nm and the switches SW1 to SWm, a resistor having a resistance value R and provided between the nodes N1 to Nm, and the like. A voltage obtained by D/A-converting the offset adjustment data is generated at the node N1 as the offset adjustment voltage VOF by switching the switches SW1 to SWm to the VREG side or the GND side based on m-bit offset adjustment data.

According to the offset adjustment circuit 60 of the R-2R ladder system, the linearity of the offset adjustment can be improved as compared with the configuration in which the temperature sensor is caused to have the offset adjustment function in this manner. Furthermore, it is also possible to prevent occurrence of the problem that the gradient characteristics of the temperature detection voltage change due to the offset adjustment.

In addition, as a modification example of the offset adjustment circuit 60, it is also possible to use a series resistor-type D/A conversion circuit including a plurality of resistors provided in series between the power supply node and the GND node and a plurality of switches provided between a plurality of resistor connection nodes and an output node of the offset adjustment voltage VOF. However, there is a problem that the layout area may increase in the configuration using the series resistor-type D/A conversion circuit. On the other hand, according to the offset adjustment circuit 60 using the R-2R ladder system of FIG. 5, there is an advantage that the layout area of the resistors is reduced as compared with the case of using the series-resistor system and the layout area of the circuit can be reduced to, for example, about 40%. Note that the offset adjustment circuit 60 is not limited to the configuration using the R-2R ladder system, and various modifications such as a configuration of a D/A conversion circuit using, for example, a series-resistor system or a capacitance-distribution system can be implemented.

In FIG. 5, the correction voltage output circuit 70 includes an operational amplifier OPB that receives an input of a power supply compensation voltage VB that changes in accordance with the power supply voltage VDD to a first input terminal and an input of the offset adjustment voltage VOF to a second input terminal and outputs the correction voltage VCR from an output terminal. The first input terminal is, for example, an inverting input terminal of the operational amplifier OPB, and the second input terminal is, for example, a non-inverting input terminal of the operational amplifier OPB. The operational amplifier OPB is a first operational amplifier. The power supply compensation voltage VB is a voltage for performing compensation in accordance with the power supply voltage VDD, and is a voltage that changes in accordance with a change in power supply voltage VDD. For example, the power supply compensation voltage VB rises when the power supply voltage VDD rises, and drops when the power supply voltage VDD drops.

As described above, since the power supply compensation voltage VB in accordance with the power supply voltage VDD is input to the first input terminal and the offset adjustment voltage VOF is input to the second input terminal of the operational amplifier OPB of the correction voltage output circuit 70, the correction voltage VCR that reflects the power supply voltage VDD and the offset adjustment voltage VOF can be output from the output terminal. For example, the correction voltage output circuit 70 can output a subtraction voltage or an addition voltage of a voltage obtained by multiplying the offset adjustment voltage VOF by a given coefficient and a voltage obtained by multiplying the power supply voltage VDD by a given coefficient as the correction voltage VCR. As a result, the temperature detection voltage VTS from the temperature sensor 50 can be corrected with the correction voltage VCR that reflects the power supply voltage VDD and the offset adjustment voltage VOF, and the corrected temperature detection voltage VTS2 can be output to the temperature compensation circuit 40.

Specifically, the correction voltage output circuit 70 includes resistors RB1 and RB2 provided in series between an input node NVD of the power supply voltage VDD and a node NB3 of an output terminal of the operational amplifier OPB. The resistor RB1 is a first resistor, and the resistor RB2 is a second resistor. The power supply compensation voltage VB from a connection node NB1 between the resistor RB1 and the resistor RB2 is supplied to the first input terminal of the operational amplifier OPB. For example, the power supply compensation voltage VB is input to the connection node NB1 of the inverting input terminal which is the first input terminal of the operational amplifier OPB. Also, the offset adjustment voltage VOF is input to the node NB2 of a non-inverting input terminal which is the second input terminal of the operational amplifier OPB. In this manner, a resistor-divided voltage obtained by the resistors RB1 and RB2 can be input to the first input terminal of the operational amplifier OPB as the power supply compensation voltage VB. As a result, the power supply compensation voltage VB that changes in accordance with the power supply voltage VDD is input to the first input terminal of the operational amplifier OPB with the second input terminal to which the offset adjustment voltage VOF is input. Therefore, the correction voltage output circuit 70 can output the correction voltage VCR that reflects the power supply voltage VDD and the offset adjustment voltage VOF.

In a case where the resistance values of the resistors RB1 and RB2 are denoted by R1 and R2, for example, the correction voltage VCR is represented by Equation (1) below.

$$VCR = ( 1 + \frac{R 2}{R 1} ) VOF - ( \frac{R 2}{R 1} ) VDD \qquad ( 1 )$$

As described above, the operational amplifier OPB is an inverting amplifier to which the offset adjustment voltage VOF and the power supply voltage VDD are input, and outputs, for example, a subtraction voltage of a voltage obtained by multiplying the offset adjustment voltage VOF by a coefficient (1+R2/R1) and a voltage obtained by multiplying the power supply voltage VDD by a coefficient (R2/R1) as the correction voltage VCR. Therefore, the correction voltage VCR that reflects the power supply voltage VDD and the offset adjustment voltage VOF is output from the correction voltage output circuit 70.

In FIG. 5, the correction circuit 74 includes an operational amplifier OPC that receives an input of the compensation voltage VC that changes in accordance with the correction voltage VCR to a first input terminal and an input of the temperature detection voltage VTS from the temperature sensor 50 to a second input terminal and outputs the corrected temperature detection voltage VTS2 from an output terminal. The first input terminal is, for example, an inverting input terminal of the operational amplifier OPC, and the second input terminal is, for example, a non-inverting input terminal of the operational amplifier OPC. The operational amplifier OPC is a second operational amplifier. The compensation voltage VC is a voltage for performing temperature compensation in accordance with the correction voltage VCR, and is a voltage that changes in accordance with a change in correction voltage VCR. For example, the compensation voltage VC rises when the correction voltage VCR rises, and drops when the correction voltage VCR drops.

As described above, since the compensation voltage VC in accordance with the correction voltage VCR is input to the first input terminal, and the temperature detection voltage VTS from the temperature sensor 50 is input to the second input terminal of the operational amplifier OPC of the correction circuit 74, the temperature detection voltage VTS2 obtained by reflecting the correction voltage VCR on the temperature detection voltage VTS can be output from the output terminal. For example, the correction circuit 74 can output, as the corrected temperature detection voltage VTS2, a subtraction voltage or an addition voltage of a voltage obtained by multiplying the temperature detection voltage VTS by a given coefficient and a voltage obtained by multiplying the correction voltage VCR by a given coefficient. As a result, the temperature detection voltage VTS from the temperature sensor 50 can be corrected with the correction voltage VCR that reflects the power supply voltage VDD and the offset adjustment voltage VOF, and the corrected temperature detection voltage VTS2 can be output to the temperature compensation circuit 40.

Specifically, the correction circuit 74 includes resistors RC1 and RC2 provided in series between an input node NVC of the correction voltage VCR and a node NC3 of an output terminal of the operational amplifier OPC. The resistor RC1 is a first resistor, and the resistor RC2 is a second resistor. The compensation voltage VC from a connection node NC1 between the resistor RC1 and the resistor RC2 is supplied to the first input terminal of the operational amplifier OPC. For example, the compensation voltage VC is input to the connection node NC1 of the inverting input terminal which is the first input terminal of the operational amplifier OPC. The temperature detection voltage VTS is input to a node NC2 of a non-inverting input terminal which is the second input terminal of the operational amplifier OPC. In this manner, a resistor-divided voltage obtained by the resistors RC1 and RC2 can be input to the first input terminal of the operational amplifier OPC as the compensation voltage VC. In this manner, the compensation voltage VC that changes in accordance with the correction voltage VCR is input to the first input terminal of the operational amplifier OPC with the second input terminal to which the temperature detection voltage VTS is input. Therefore, the correction circuit 74 can output, as the corrected temperature detection voltage VTS2, a voltage obtained by correcting the temperature detection voltage VTS from the temperature sensor 50 with the correction voltage VCR that changes in accordance with the power supply voltage VDD and the offset adjustment voltage VOF.

In a case where the resistance values of the resistors RC1 and RC2 are denoted by R3 and R4, for example, the temperature detection voltage VTS2 corrected by the correction circuit 74 is represented by Equation (2) below.

$$VTS 2 = ( 1 + \frac{R 4}{R 3} ) VTS - ( \frac{R 4}{R 3} ) VCR \qquad ( 2 )$$

As described above, the operational amplifier OPC is an inverting amplifier to which the temperature detection voltage VTS and the correction voltage VCR are input, and outputs, for example, a subtraction voltage between a voltage obtained by multiplying the temperature detection voltage VTS by a coefficient (1+R4/R3) and a voltage obtained by multiplying the correction voltage VCR by a coefficient (R4/R3) as represented by Equation (2) above as the corrected temperature detection voltage VTS2. The correction voltage VCR is a voltage that changes in accordance with the power supply voltage VDD and the offset adjustment voltage VOF as represented by Equation (1) above. Therefore, the temperature detection voltage VTS2 obtained by correcting the temperature detection voltage VTS from the temperature sensor 50 based on the power supply voltage VDD and the offset adjustment voltage VOF as represented by Equation (3) above is output from the correction circuit 74.

Next, the correction with the correction voltage VCR will be described in detail. In the present embodiment, the resistance ratio Rr=(R2/R1) between the resistors RB1 and RB2 of the correction voltage output circuit 70 is variable, or at least one of the resistance value R1 of the resistor RB1 and the resistance value R2 of the resistor RB2 is variable. In this manner, how to reflect each of the power supply voltage VDD and the offset adjustment voltage VOF on the correction voltage VCR can be variably controlled by the resistance ratio Rr or the resistance values of the resistors RB1 and RB2.

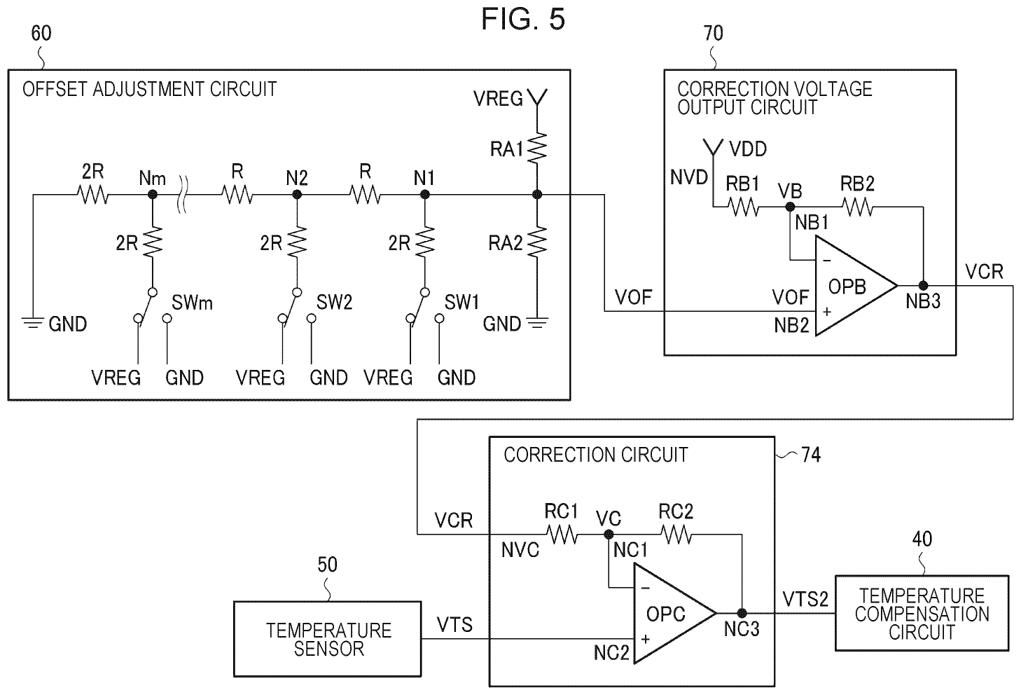

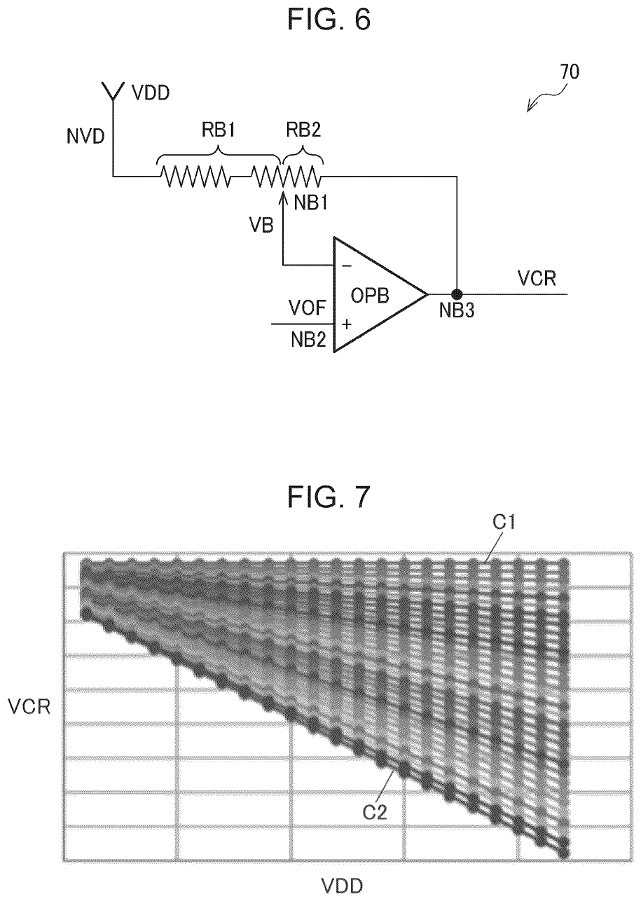

FIG. 6 illustrates a detailed configuration example of the correction voltage output circuit 70. In FIG. 6, a plurality of resistors are connected in series between the input node NVD of the power supply voltage VDD and the node NB3 of the output terminal of the operational amplifier OPB. Also, nodes of connection taps of the plurality of resistors are connected to the first input terminal (inverting input terminal) of the operational amplifier OPB as the connection node NB1. For example, a plurality of switches are provided between the plurality of connection taps and the first input terminal of the operational amplifier OPB, and by any of the switches being turned on based on adjustment data, a connection tap connected to the switch that has been turned on is connected to the first input terminal of the operational amplifier OPB. The resistor RB1 corresponds to a resistor between the connection tap and the input node NVD of the power supply voltage VDD, and the resistor RB2 corresponds to a resistor between the connection tap and the node NB3 of the output terminal. In this manner, the resistance ratio Rr=(R2/R1) between the resistor RB1 and the resistor RB2 is variably controlled based on the adjustment data of the correction voltage output circuit 70. As a result, it is possible to variably control how to reflect each of the power supply voltage VDD and the offset adjustment voltage VOF on the correction voltage VCR as represented by VCR=(1+R2/R1)VOF−(R2/R1) VDD in Equation (1) above.

FIG. 7 is an explanatory diagram of a setting example of the correction voltage VCR. In FIG. 7, the horizontal axis represents the power supply voltage VDD, and the vertical axis represents the correction voltage VCR. C1 represents characteristics of the temperature detection voltage VTS2 in a case where the resistance ratio Rr=(R2/R1) adjusted with adjustment data of n=4 bits is the smallest, and C2 represents characteristics of the temperature detection voltage VTS2 in a case where the resistance ratio Rr=(R2/R1) is the largest. Note that only the resistance value R1 of the resistor RB1 may be controlled, only the resistance value R2 of the resistor RB2 may be controlled, or both the resistance values R1 and R2 may be controlled, based on the adjustment data. In this case, C1 in FIG. 7 represents characteristics of the temperature detection voltage VTS2 in the case where the resistance value R2 is the smallest, and C2 represents characteristics of the temperature detection voltage VTS2 in the case where the resistance value R2 is the largest. The adjustment data of the correction voltage output circuit 70 is, for example, n-bit (n is an integer equal to or greater than two) data and is stored in, for example, the nonvolatile memory 110 in FIG. 2.

As illustrated in FIG. 7, the correction voltage output circuit 70 outputs, as the correction voltage VCR, a voltage that monotonically decreases in accordance with a rise in the power supply voltage VDD and has a variable amount of change in voltage with respect to a variation in the power supply voltage VDD. In this manner, the temperature compensation is performed using the correction voltage VCR which monotonically decreases when the power supply voltage VDD rises and has the variable amount of change in voltage with respect to a variation in the power supply voltage VDD for the correction of the temperature detection voltage VTS of the temperature sensor 50. It is thus possible to prevent occurrence of an error in the oscillation frequency due to excessive temperature compensation of the temperature compensation voltage VCP. Note that the correction voltage VCR may be a voltage that monotonically increases in accordance with a rise in the power supply voltage VDD. In a case where a variable capacitance circuit having negative characteristics is used as the variable capacitance circuit for temperature compensation, for example, the correction voltage VCR may be monotonically increased in accordance with a rise in the power supply voltage VDD.

The correction circuit 74 corrects the temperature detection voltage VTS of the temperature sensor 50 with such a correction voltage VCR and outputs the corrected temperature detection voltage VTS2. For example, the corrected temperature detection voltage VTS2 is represented by Equation (3) below using the temperature detection voltage VTS, the offset adjustment voltage VOF, and the power supply voltage VDD from Equations (1) and (2) above.

$$VTS 2 = ( 1 + \frac{R 4}{R 3} ) VTS - ( \frac{R 4}{R 3} ) VCR = ( 1 + \frac{R 4}{R 3} ) VTS - ( \frac{R 4}{R 3} ) ( 1 + \frac{R 2}{R 1} ) VOF + ( \frac{R 4}{R 3} ) ( \frac{R 2}{R 1} ) VDD \qquad ( 3 )$$

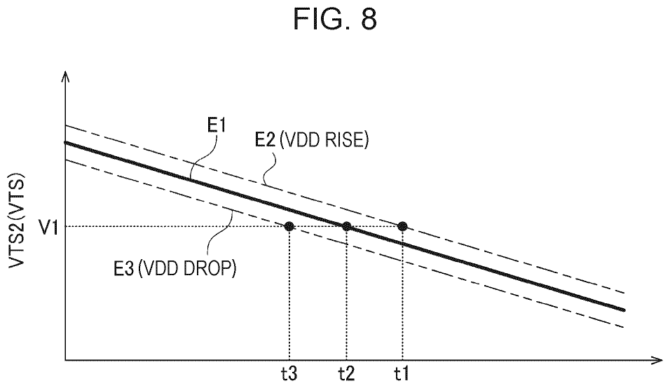

Therefore, the corrected temperature detection voltage VTS2 changes in accordance with a variation in the power supply voltage VDD as represented by Equation (3) above, and temperature compensation that reflects the variation in power supply voltage VDD can be realized. FIG. 8 illustrates an example of temperature characteristics of the temperature detection voltage. As illustrated in FIG. 8, the temperature detection voltage has, for example, negative temperature characteristics with respect to the temperature T. Also, E1 in FIG. 8 represents temperature characteristics of the temperature detection voltage VTS2 when the power supply voltage VDD is a typical voltage, E2 represents temperature characteristics when VDD rises, and E3 represents temperature characteristics when VDD drops.

For example, it is assumed that when the power supply voltage VDD rises, the temperature at the location of the temperature sensor 50 is T=t1. In this case, the correction circuit 74 outputs a voltage of VTS2=V1 as the corrected temperature detection voltage. As illustrated in FIG. 8, the voltage of VTS2=V1 corresponds to the temperature detection voltage at the temperature T=t2 when the power supply voltage VDD is a typical voltage. In other words, when the power supply voltage VDD rises, the correction circuit 74 outputs the temperature detection voltage VTS2 corresponding to the temperature T=t2 that is lower than the temperature T=t1 at the location of the temperature sensor 50.

It is also assumed that when the power supply voltage VDD drops, the temperature at the location of the temperature sensor 50 is T=t3. In this case, the correction circuit 74 outputs, as the corrected temperature detection voltage, the temperature detection voltage VTS2=V1 corresponding to the temperature T=t2 when the power supply voltage VDD is a typical voltage. In other words, when the power supply voltage VDD drops, the correction circuit 74 outputs the temperature detection voltage VTS2 corresponding to the temperature T=t2 that is higher than the temperature T=t3 at the location of the temperature sensor 50.

As described above, when the power supply voltage VDD rises, the temperature rise of the circuit device 20 is larger than the temperature rise of the resonator 10, and the temperature at the location of the temperature sensor 50 of the circuit device 20 is higher than the temperature at the resonator 10.

Therefore, when the power supply voltage VDD rises, the correction circuit 74 outputs the temperature detection voltage VTS2 corresponding to the temperature T=t2 that is lower than the temperature T=t1 as illustrated in FIG. 8. As a result, the temperature detection voltage VTS2 corresponding to the temperature at the location of the resonator 10 where the temperature is lower than that at the location of the circuit device 20 is input to the temperature compensation circuit 40, and it is possible to prevent excessive temperature compensation as indicated by A4 and A5 in FIG. 3 from being performed. Furthermore, when the power supply voltage VDD drops, the correction circuit 74 outputs the temperature detection voltage VTS2 corresponding to the temperature T=t2 that is higher than the temperature T=t3. As a result, it is possible to prevent excessive temperature compensation as indicated by A4 and A5 in FIG. 3 from being performed.

Furthermore, the coefficient of the power supply voltage VDD in Equation (3) above is defined as cf (Rr)=(R4/R3)(R2/R1)=(R4/R3) Rr. The coefficient cf (Rr) increases as the resistance ratio Rr=R2/R1 in the correction voltage output circuit 70 in FIG. 6 increases. For example, the smaller the oscillator 4 is and the smaller the heat capacity is, the larger the amount of change in temperature due to a variation in the power supply voltage VDD is. Therefore, the resistance ratio Rr=R2/R1 is increased to increase the coefficient cf (Rr) as indicated by C2 in FIG. 7. As described above, the correction circuit 74 can adjust the coefficient cf (Rr) of the power supply voltage VDD by setting the resistance ratio Rr and the resistance values R1 and R2. Therefore, it is possible to realize appropriate temperature compensation in accordance with the heat capacity of the oscillator 4 by setting the resistance ratio Rr and the resistance values R1 and R2 in accordance with the heat capacity of the oscillator 4. For example, adjustment data of the resistance ratio Rr and the resistance values R1 and R2 can be stored in the nonvolatile memory 110 as described above. Therefore, it is possible to realize appropriate temperature compensation in accordance with the heat capacity of the products by writing appropriate adjustment data in accordance with the products of the oscillator 4 and the circuit device 20 in the nonvolatile memory 110.

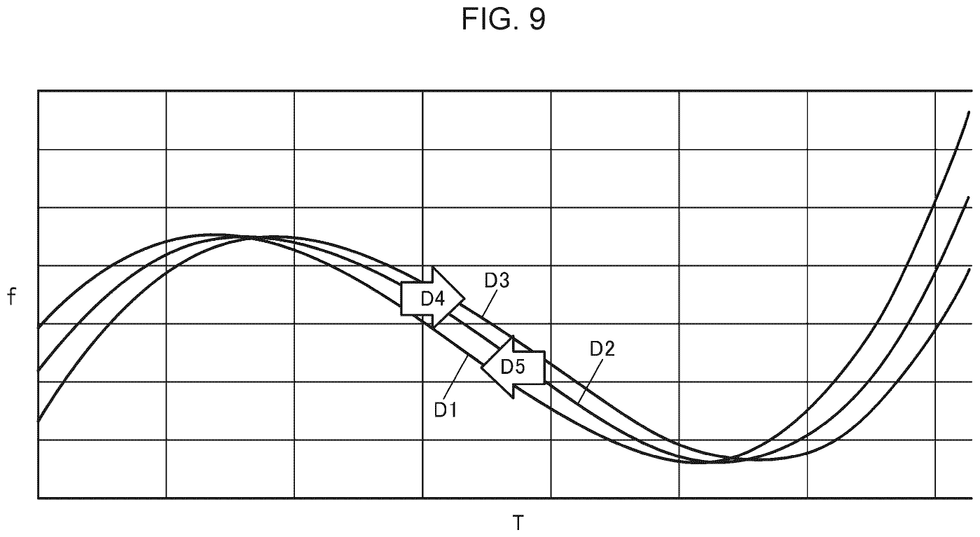

FIG. 9 is an explanatory diagram of a correction method of the present embodiment. In FIG. 9, D1 represents frequency-temperature characteristics of the resonator 10 before the power supply voltage VDD rises, and D2 represents frequency-temperature characteristics of the resonator 10 after the power supply voltage VDD rises. D1 and D2 indicate a case where temperature compensation is adequately performed based on a temperature TX of the resonator 10. On the other hand, D3 represents frequency-temperature characteristics of the temperature compensation voltage VCP when temperature compensation is excessively performed with a temperature TJ detected by the temperature sensor 50 of the circuit device 20 after the power supply voltage VDD rises. As described above, when the variable capacitance circuit 32 having positive capacitance change characteristics is used, the capacitance increases and the oscillation frequency drops if the temperature compensation voltage VCP rises, or the capacitance decreases and the oscillation frequency rises if the temperature compensation voltage VCP drops, and compensation for the frequency-temperature characteristics of the resonator 10 is thus performed with the temperature compensation voltage VCP having the frequency-temperature characteristics as indicated by D3.

Since excessive temperature compensation based on the temperature TJ detected by the temperature sensor 50 is performed as indicated by D4, and temperature compensation based on the temperature compensation voltage VCP indicated by D3 is performed when the power supply voltage VDD rises in FIG. 9, an error in the oscillation frequency due to an error in the temperature compensation occurs. Therefore, the correction circuit 74 of the present embodiment performs correction as indicated by D5 to prevent excessive temperature compensation as indicated by D4 from being performed. In this manner, it is possible to suppress the occurrence of an error in the oscillation frequency due to excessive temperature compensation.

In other words, a temperature difference TJ-TX occurs between the temperature TJ detected by the temperature sensor 50 of the circuit device 20 and the temperature TX of the resonator. As indicated by A4 and A5 in FIGS. 3 and B4 and B5 in FIG. 4, the temperature difference TJ-TX increases as a variation in the power supply voltage VDD increases. Therefore, when the temperature difference TJ-TX between the temperature TJ detected by the temperature sensor 50 and the temperature TX of the resonator 10 changes due to a variation in the power supply voltage VDD, the correction circuit 74 of the present embodiment changes the temperature detection voltage VTS2 by the amount of change in voltage corresponding to the temperature difference TJ-TX. For example, the correction circuit 74 performs correction to change the temperature detection voltage VTS2 by the amount of change in voltage that increases as the temperature difference TJ-TX increases. This correction is realized by a change in correction voltage VCR from the correction voltage output circuit 70. In FIG. 3, for example, the temperature difference TJ-TX between the temperature TJ detected by the temperature sensor 50 and the temperature TX of the resonator 10 is larger in the case of A5 in which VDD is +10% than in the case of A4 in which VDD is +5%. Therefore, the correction circuit 74 performs correction to change the temperature detection voltage VTS2 by a larger amount of change in voltage in the case of A5 in which the power supply voltage VDD significantly varies and the temperature difference TJ-TX increases than in the case of A4. Even in a case where the power supply voltage VDD drops as in FIG. 4, the correction circuit 74 performs correction to change the temperature detection voltage VTS2 by the amount of change in voltage that increases as the temperature difference TJ-TX increases. In this manner, even in a case where the temperature difference TJ-TX between the temperature TJ detected by the temperature sensor 50 and the temperature TX of the resonator 10 is changed due to a variation in the power supply voltage VDD, it is possible to reduce an error in the temperature compensation due to the temperature difference TJ-TX and to improve accuracy of the oscillation frequency.

In this manner, correction to return the frequency-temperature characteristics indicated by D3 obtained by excessively performing the temperature compensation to the adequate frequency-temperature characteristics indicated by D2 is performed as indicated by D5 in FIG. 9. In other words, correction is performed to shift the frequency-temperature characteristics in a direction opposite to the direction in which the excessive temperature compensation has been performed, along the horizontal axis which is the axis of the temperature T. In this manner, it is possible to perform correction for reducing the error due to the excessive temperature compensation, and to achieve an improvement in the accuracy of the oscillation frequency and the like.

### 3. Temperature Compensation Circuit

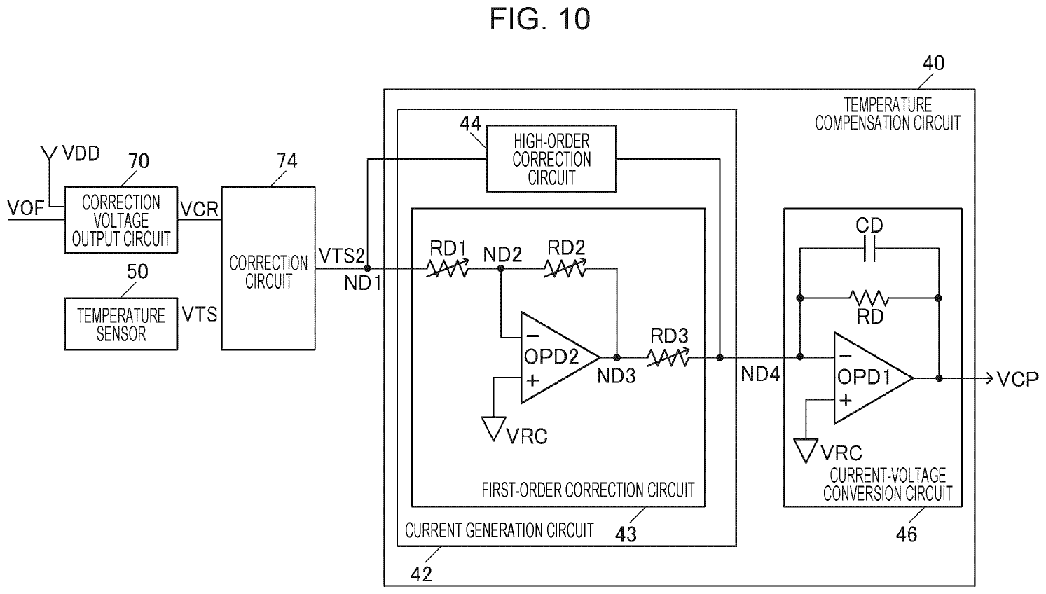

FIG. 10 illustrates a configuration example of the temperature compensation circuit 40. Note that the temperature compensation circuit 40 is not limited to the configuration of FIG. 10, and various modifications such as omitting some of the components, adding other components, or replacing some of the components with other components can be made.

The temperature compensation circuit 40 is a circuit that outputs the temperature compensation voltage VCP by polynomial approximation using a temperature as a variable. The temperature compensation circuit 40 includes a current generation circuit 42 and a current-voltage conversion circuit 46. The current generation circuit 42 generates a functional current based on a result of detecting a temperature by the temperature sensor 50. For example, the temperature detection voltage VTS, which is the result of detecting the temperature by the temperature sensor 50, is corrected by the correction circuit 74, and the current generation circuit 42 generates a functional current for temperature-compensating the frequency-temperature characteristics of the resonator 10 based on the corrected temperature detection voltage VTS2 from the correction circuit 74. Then, the current-voltage conversion circuit 46 converts the functional current from the current generation circuit 42 into a voltage and outputs the temperature compensation voltage VCP. Specifically, the current-voltage conversion circuit 46 outputs the temperature compensation voltage VCP by an operational amplifier OPD1.

The current generation circuit 42 includes a first-order correction circuit 43 and a high-order correction circuit 44. The first-order correction circuit 43 outputs a first-order current that approximates a linear function based on the temperature detection voltage VTS2. For example, the first-order correction circuit 43 outputs a linear functional current based on first-order correction data corresponding to a first-order coefficient of a polynomial in the polynomial approximation. The high-order correction circuit 44 outputs a high-order current that approximates a high-order function to the current-voltage conversion circuit 46 based on the temperature detection voltage VTS2. For example, the high-order correction circuit 44 outputs a high-order current based on high-order correction data corresponding to a high-order coefficient of a polynomial in the polynomial approximation. In one example, the high-order correction circuit 44 outputs a third-order current that approximates a cubic function. In this case, the high-order correction circuit 44 includes a differential circuit that performs a differential operation based on the temperature detection voltage VTS2, and a differential circuit that outputs a third-order current by performing a differential operation based on a voltage output by the differential circuit and the temperature detection voltage VTS2. Note that the high-order correction circuit 44 may further include a correction circuit that performs fourth- or higher order correction. For example, the high-order correction circuit 44 may further include a fourth-order correction circuit that outputs a fourth-order current that approximates a quartic function, a fifth-order correction circuit that outputs a fifth-order current that approximates a quintic function, and the like.

The first-order correction circuit 43 includes an operational amplifier OPD2 and resistors RD1 and RD2. The first-order correction circuit 43 can include a resistor RD3 having a variable resistance value. A reference voltage VRC is input to a non-inverting input terminal of the operational amplifier OPD2. The resistor RD1 is provided between an input node ND1 of the temperature detection voltage VTS2 and a node ND2 of the inverting input terminal of the operational amplifier OPD2. The resistor RD2 is provided between the node ND2 of the inverting input terminal of the operational amplifier OPD2 and a node ND3 of an output terminal of the operational amplifier OPD2. The resistor RD3 is provided between the node ND3 of the output terminal of the operational amplifier OPD2 and an output node ND4 of the current generation circuit 42.

The current-voltage conversion circuit 46 outputs the temperature compensation voltage VCP by adding the first-order current and the high-order current and current-voltage converting the added current. As a result, the temperature compensation voltage VCP that approximates a polynomial function is generated. Specifically, the current-voltage conversion circuit 46 includes the operational amplifier OPD1 and a feedback circuit element. The operational amplifier OPD1 has a non-inverting input terminal to which the reference voltage VRC is input and an inverting input terminal to which the output node ND4 of the current generation circuit 42 is connected. The feedback circuit element is a circuit element provided between the output terminal of the operational amplifier OPD1 and the inverting input terminal of the operational amplifier OPD1. In FIG. 10, a resistor RD and a capacitor CD are provided in parallel as feedback circuit elements between the output terminal and the inverting input terminal of the operational amplifier OPD1.

In this manner, the temperature compensation circuit 40 in FIG. 10 includes the first-order correction circuit 43 and the high-order correction circuit 44 to which the corrected temperature detection voltage VTS2 is input, and includes the current generation circuit 42 that generates the functional current by the first-order correction circuit 43 and the high-order correction circuit 44, and the current-voltage conversion circuit 46 that converts the functional current into a voltage and outputs the temperature compensation voltage VCP. According to the temperature compensation circuit 40 having such a configuration, the functional current generated by the current generation circuit 42 based on the corrected temperature detection voltage VTS2 can be converted into a voltage by the current-voltage conversion circuit 46 and output as the temperature compensation voltage VCP.

### 4. Temperature Sensor

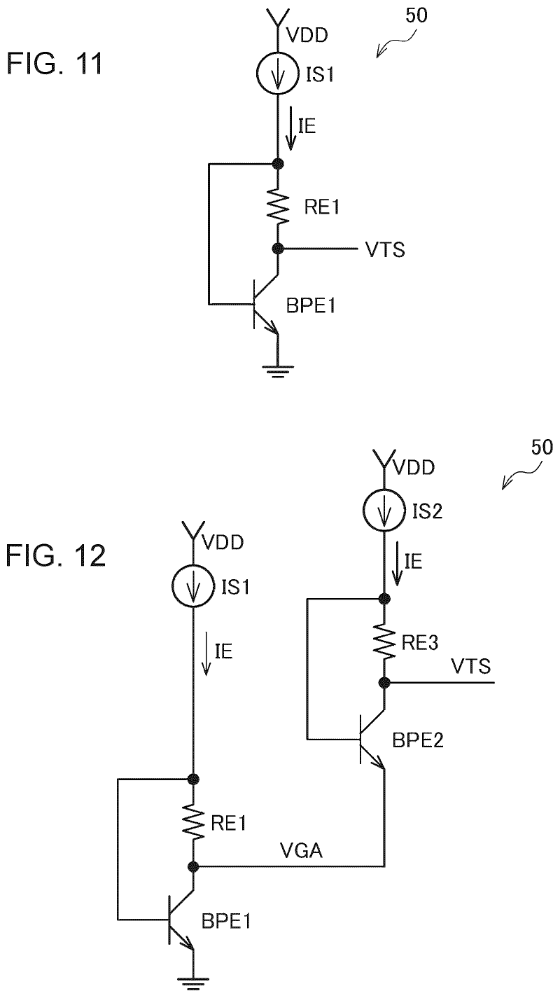

Next, a configuration example of the temperature sensor 50 will be described. FIG. 11 illustrates a first configuration example of the temperature sensor 50. The temperature sensor 50 includes a constant current source IS1, a bipolar transistor BPE1, and a resistor RE1. The constant current source IS1, the resistor RE1, and the bipolar transistor BPE1 are provided in series between the VDD node and the GND node. Specifically, a connection node between the constant current source IS1 and one end of the resistor RE1 is connected to a base of the bipolar transistor BPE1, and the other end of the resistor RE1 is connected to a collector of the bipolar transistor BPE1. An emitter of the bipolar transistor BPE1 is connected to the GND node.

When a current flowing from the constant current source IS1 is denoted by IE, a resistance value of the resistor RE1 is denoted by R1, and a base-emitter voltage of the bipolar transistor BPE1 is denoted by VBE1 in FIG. 11, the temperature detection voltage VTS is represented as Equation (4) below.

$$VTS = VBE 1 - IE \times R 1 \qquad ( 4 )$$

Since the base-emitter voltage VBE1 of the bipolar transistor BPE1 has negative temperature characteristics, the temperature detection voltage VTS also has negative temperature characteristics.

FIG. 12 illustrates a second configuration example of the temperature sensor 50. The temperature sensor 50 in FIG. 12 includes constant current sources IS1 and IS2, bipolar transistors BPE1 and BPE2, and resistors RE1 and RE3.

The connection configuration of the constant current source IS1, the bipolar transistor BPE1, and the resistor RE1 is similar to that in the first configuration example of FIG. 11. The constant current source IS2, the resistor RE3, and the bipolar transistor BPE2 are provided in series between the VDD node and the node of the collector of the bipolar transistor BPE1. Specifically, a connection node between the constant current source IS2 and one end of the resistor RE3 is connected to a base of the bipolar transistor BPE2, and the other end of the resistor RE3 is connected to a collector of the bipolar transistor BPE2. Also, an emitter of the bipolar transistor BPE2 is connected to the collector of the bipolar transistor BPE1.

In FIG. 12, a voltage of the collectors of the bipolar transistors BPE1 and BPE2 is denoted by VGA, a current flowing through the constant current sources IS1 and IS2 is denoted by IE, and the resistance values of the resistors RE1 and RE3 are denoted by R1 and R3, respectively. Also, base-emitter voltages of the bipolar transistors BPE1 and BPE2 are denoted by VBE1 and VBE2, respectively. Then, the voltages VGA and VTS are represented as Equations (5) and (6) below. Here, an offset voltage of the operational amplifier OPE is assumed to be zero.

$$\begin{matrix}VGA = VBE 1 - IE \times R 1 & ( 5 ) \\ \begin{matrix}VTS = VBE 2 - IE \times R 3 + VGA \\ = VBE 1 + VBE 2 - IE \times ( R 1 + R 3 )\end{matrix} & ( 6 )\end{matrix}$$

Since the bipolar transistors BPE1 and BPE2 of two stages are provided in the second configuration example of FIG. 12, two base-emitter voltages VBE1 and VBE2 are added. Accordingly, it is possible to increase the gradient of the temperature detection voltage VTS with respect to the temperature and to generate the temperature detection voltage VTS having higher sensitivity with respect to the temperature as compared with the first configuration example of FIG. 11.

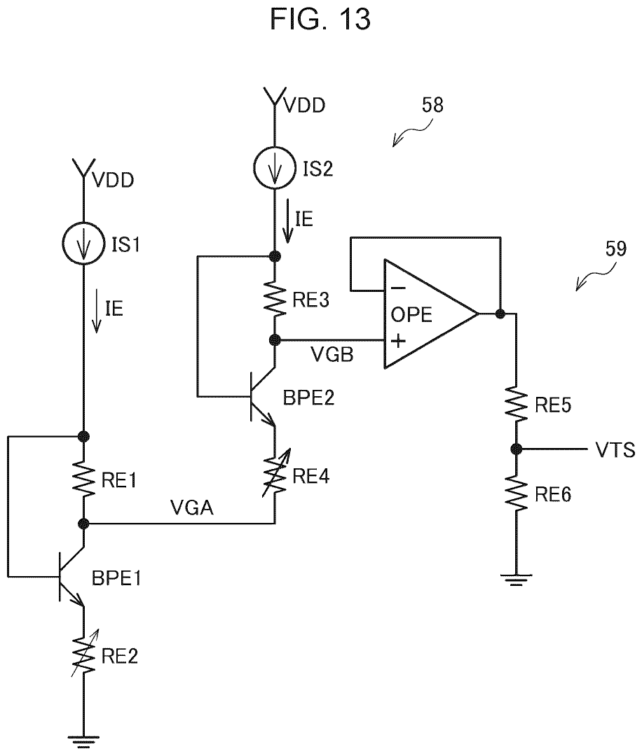

FIG. 13 illustrates a configuration of a temperature sensor 58 as a comparative example of the present embodiment. The temperature sensor 58 in FIG. 13 has the configuration disclosed in JP-A-2023-090099. In the comparative example of FIG. 13, a buffer circuit 59 including resistors RE2 and RE4 having variable resistance values, an operational amplifier OPE, and resistors RE5 and RE6 is further provided in addition to the configuration in FIG. 12. Zero-order offset adjustment of the temperature detection voltage VTS can be performed by changing the resistance values of the resistors RE2 and RE4. As a result, the temperature detection voltage VTS includes an offset component, and the zero-order offset adjustment by the temperature sensor 58 can be performed. Furthermore, it is possible to output the temperature detection voltage VTS by the operational amplifier OPE having a high driving capability by providing the buffer circuit 59 in FIG. 13.

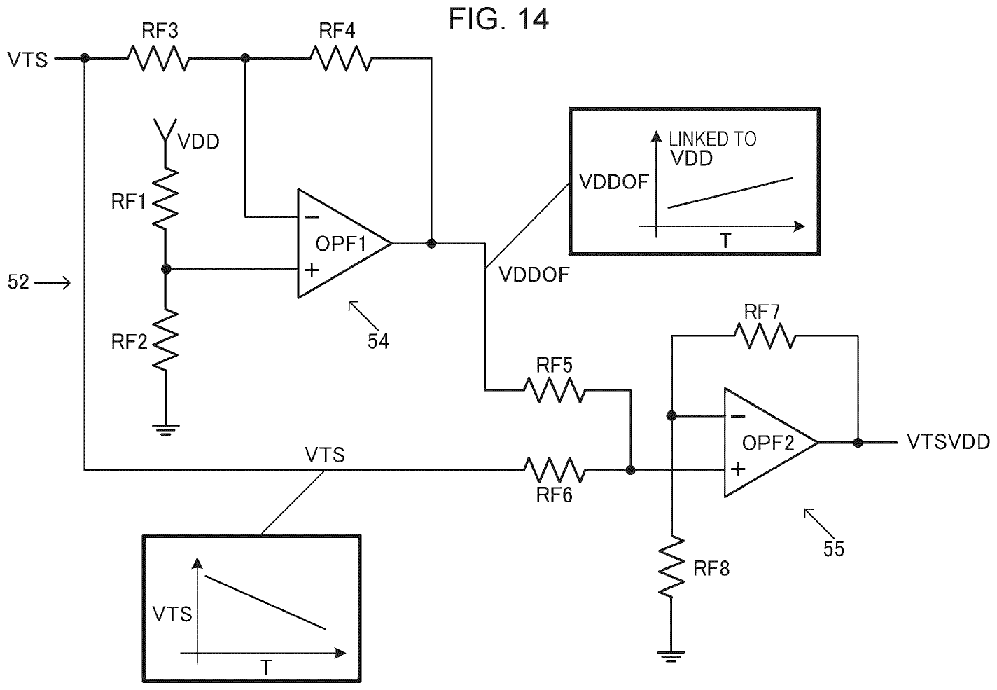

FIG. 14 illustrates a configuration of a correction circuit 52 in the comparative example. The correction circuit 52 in FIG. 14 has a configuration disclosed in JP-A-2023-090099. In FIG. 14, the correction circuit 52 includes an offset generation circuit 54 and an addition circuit 55. The offset generation circuit 54 includes an operational amplifier OPF1 and resistors RF1, RF2, RF3, and RF4, receives inputs of the power supply voltage VDD and the temperature detection voltage VTS, and generates an offset voltage VDDOF for VDD compensation. The offset voltage VDDOF is a voltage that changes in a manner linked to the power supply voltage VDD, and is an offset voltage for compensating a change in power supply voltage VDD. The addition circuit 55 includes an operational amplifier OPF2 and resistors RF5, RF6, RF7, and RF8, adds the temperature detection voltage VTS from the temperature sensor 58 and the offset voltage VDDOF for VDD compensation, and outputs a temperature detection voltage VTSVDD.

In the temperature sensor 58 of the comparative example in FIG. 13, offset adjustment of the temperature detection voltage VTS is performed based on zero-order correction data corresponding to a zero-order coefficient of a polynomial in polynomial approximation of the temperature compensation characteristics. For example, the zero-order offset adjustment can be performed by adjusting the resistance values of the resistors RE2 and RE4 in the temperature sensor 58.

However, the temperature sensor 58 of the comparative example in FIG. 13 has a problem that linearity of the offset adjustment is degraded due to the zero-order offset adjustment being performed in a distributed manner at a plurality of locations. For example, the linearity of the offset adjustment is degraded due to the offset adjustment of the temperature detection voltage VTS at a plurality of locations, such as adjustment of the resistance value of the resistor RE2 and adjustment of the resistance value of the resistor RE4. For example, although an adjustment range by the resistor RE2 and an adjustment range by the resistor RE4 are set to overlap each other such that the offset adjustment can be adequately performed even in a case where a manufacturing process varies, the linearity is degraded at a location corresponding to the overlapping adjustment range. Furthermore, the comparative example in FIG. 13 also has a problem that gradient characteristics of the temperature detection voltage VTS with respect to the temperature changes due to the offset adjustment.

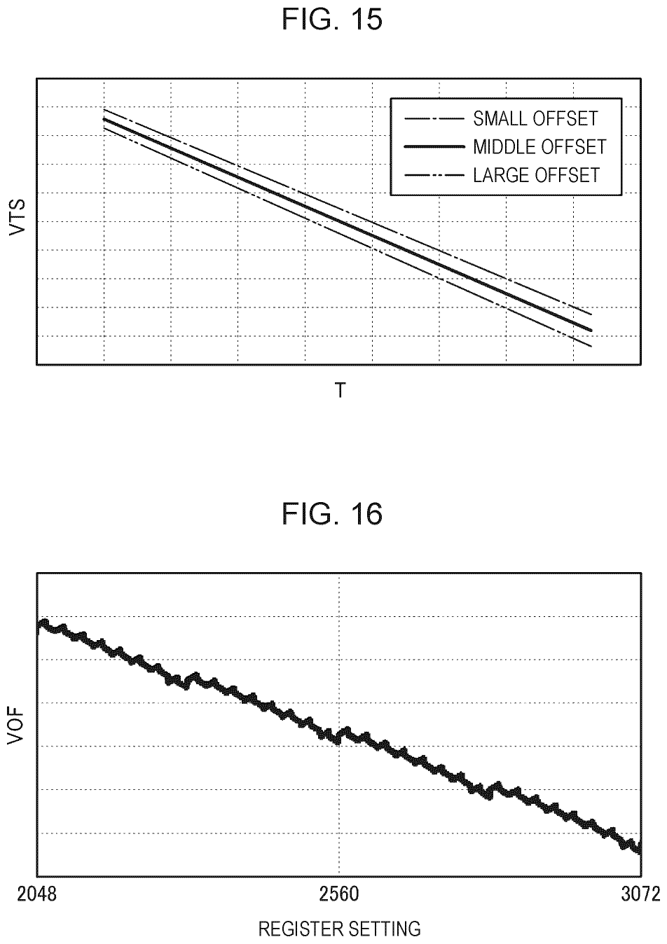

For example, FIG. 15 illustrates temperature characteristics of the temperature detection voltage VTS when the zero-order offset adjustment voltage is changed in the temperature sensor 58 of the comparative example in FIG. 13. As illustrated in FIG. 15, the gradient of the temperature detection voltage VTS with respect to the temperature T changes in accordance with the magnitude of the offset adjustment voltage in the temperature sensor 58 of the comparative example. For example, the gradient of the temperature detection voltage VTS increases in a case where the offset adjustment voltage is large, and the gradient decreases in a case where the offset adjustment voltage is small in FIG. 15. If the gradient of the temperature detection voltage VTS changes depending on the offset adjustment voltage in this manner, then it becomes difficult to realize adequate temperature compensation.

FIG. 16 is a diagram for explaining linearity of the offset adjustment voltage of the temperature sensor 58 of the comparative example. Although the offset adjustment voltage is adjusted by register setting of the offset adjustment data in the comparative example, the linearity of the offset adjustment is degraded, for example, at the location corresponding to the overlapping adjustment range as illustrated in FIG. 16. If the linearity of the offset adjustment is degraded in this manner, it becomes difficult to realize adequate temperature compensation.

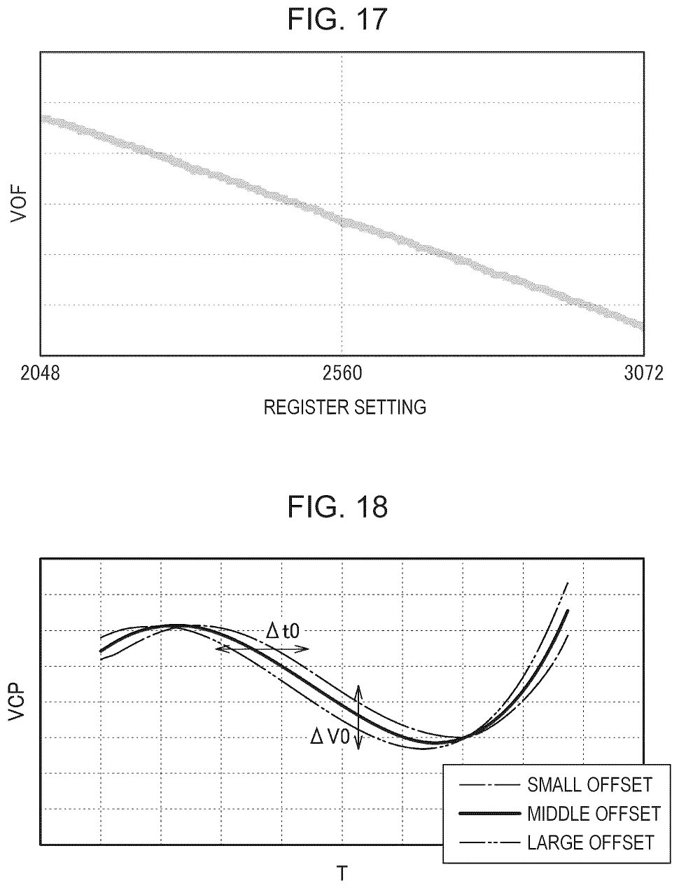

On the other hand, FIG. 17 is a diagram for explaining linearity of the offset adjustment voltage in the present embodiment. As illustrated in FIG. 17, according to the present embodiment, it is possible to greatly improve the linearity of the offset adjustment voltage as compared with the comparative example in FIG. 16.

In the comparative example, the temperature sensor 58 is provided with the operational amplifier OPE which is a buffer amplifier of the temperature detection voltage VTS, and the correction circuit 52 is provided with the operational amplifier OPF1 which is a generation amplifier of the offset voltage VDDOF for VDD compensation and the operational amplifier OPF2 which is an addition amplifier as illustrated in FIGS. 13 and 14. Therefore, a total of three amplifiers are required, which causes problems such as an increase in circuit area and an increase in current consumption.

On the other hand, since it is only necessary to provide the two operational amplifiers OPB and OPC serving as inverting amplifiers in the present embodiment in FIG. 5, the number of amplifiers can be reduced as compared with the comparative example in FIGS. 13 and 14, and there is an advantage that reduction of the circuit area and reduction of current consumption can be realized. For example, the temperature detection voltage VTS from the temperature sensor 50 is input to a gate of the differential transistor serving as the non-inverting input terminal of the operational amplifier OPC of the correction circuit 74 in FIG. 5. Therefore, the operational amplifier OPE of the buffer circuit 59 as illustrated in FIG. 13 becomes unnecessary. Furthermore, the operational amplifier OPB of the correction voltage output circuit 70 to which the power supply voltage VDD is input also serves as a buffer amplifier of the offset adjustment circuit 60. As a result, the number of amplifiers can be reduced as compared with the comparative example in FIGS. 13 and 14, and reduction of circuit area and reduction of current consumption can be achieved in FIG. 5.

In the present embodiment, the temperature detection voltage VTS2 corrected by the correction circuit 74 is input to the high-order correction circuit 44 of the temperature compensation circuit 40 as illustrated in FIG. 10. Thus, the correction of temperature compensation including the high-order correction of the high-order correction circuit 44 can be performed.

If the zero-order offset adjustment is performed, for example, an inflection point temperature in the high-order correction changes in addition to the zero-order offset. In a case where, for example, the ambient temperature is denoted by t, the temperature detected by the temperature sensor 50 is denoted by to, the amount of change in inflection point temperature is denoted by Δt0, the amount of change in zero-order offset adjustment voltage is denoted by ΔV0, and coefficients are denoted by a and b, the temperature compensation voltage VCP is represented by Equation (7) below.

$$VCP = {a ( t - t 0 - Δ t 0 )}^{3} + b ( t - t 0 - Δ t 0 ) + VOF + Δ V 0 \qquad ( 7 )$$

In Equation (7) above, the term of the coefficient a corresponds to high-order correction of a third order. As illustrated in FIG. 18, the inflection point temperature of the high-order correction also changes in accordance with the change in the offset adjustment voltage. Therefore, it is possible to realize adequate temperature compensation corresponding to the change in inflection point temperature as well by the temperature detection voltage VTS2 corrected in accordance with the temperature difference between the circuit device 20 and the resonator 10 being input to the high-order correction circuit 44 of the temperature compensation circuit 40.

### 5. Oscillator

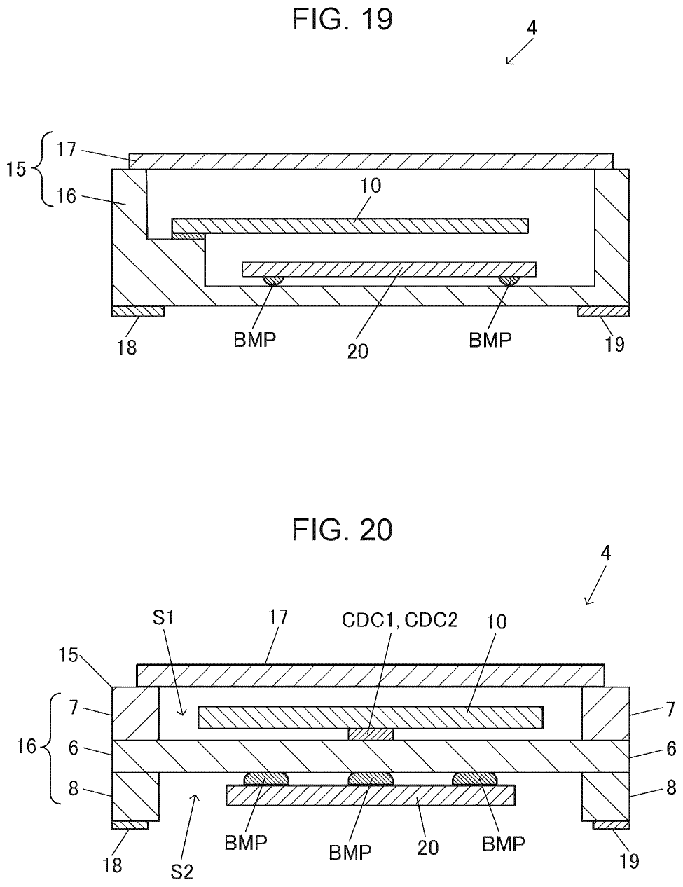

FIG. 19 illustrates a first structure example of the oscillator 4 of the present embodiment. The oscillator 4 includes the resonator 10, the circuit device 20, and the package 15 that accommodates the resonator 10 and the circuit device 20. The package 15 is formed of, for example, ceramic or the like and has an accommodation space therein, and the resonator 10 and the circuit device 20 are accommodated in the accommodation space. The accommodation space is hermetically sealed and is desirably in a reduced pressure state which is a state close to vacuum. The package 15 can suitably protect the resonator 10 and the circuit device 20 from impact, dust, heat, moisture, and the like.

The package 15 includes a base 16 and a lid 17. Specifically, the package 15 is configured of a base 16 that supports the resonator 10 and the circuit device 20 and a lid 17 that is bonded to an upper surface of the base 16 to form an accommodation space with the base 16. The resonator 10 is supported by a stepped portion provided inside the base 16 via a terminal electrode. The circuit device 20 is disposed on an inner bottom surface of the base 16. Specifically, the circuit device 20 is disposed such that an active surface faces the inner bottom surface of the base 16. The active surface is a surface on which circuit elements of the circuit device 20 are formed. Bumps BMP are formed on a terminal of the circuit device 20. The circuit device 20 is supported on the inner bottom surface of the base 16 via the conductive bumps BMP. The conductive bumps BMP are, for example, metal bumps, and the resonator 10 and the circuit device 20 are electrically connected to each other via the bumps BMP, internal wiring of the package 15, the terminal electrode, and the like. In addition, the circuit device 20 is electrically connected to the external terminals 18 and 19 of the oscillator 4 via the bumps BMP and internal wiring of the package 15. The external terminals 18 and 19 are formed on an outer bottom surface of the package 15. The external terminals 18 and 19 are connected to an external device via external wiring. The external wiring is, for example, wiring formed on a circuit substrate on which the external device is mounted. Thus, a clock signal and the like can be output to the external device.

Although the circuit device 20 is flip-mounted such that the active surface of the circuit device 20 faces downward in FIG. 19, the present embodiment is not limited to such mounting. For example, the circuit device 20 may be mounted such that the active surface of the circuit device 20 faces upward. In other words, the circuit device 20 is mounted such that the active surface faces the resonator 10.

FIG. 20 illustrates a second structure example of the oscillator 4. The oscillator 4 includes the resonator 10, the circuit device 20, and the package 15 that accommodates the resonator 10 and the circuit device 20, and the package 15 includes the base 16 and the lid 17. The base 16 includes a first substrate 6 which is an intermediate substrate, a second substrate 7 which is stacked on the side of an upper surface of the first substrate 6 and has a substantially rectangular frame shape, and a third substrate 8 which is stacked on the side of a bottom surface of the first substrate 6 and has a substantially rectangular frame shape. The lid 17 is bonded to an upper surface of the second substrate 7, and the resonator 10 is accommodated in an accommodation space S1 formed by the first substrate 6, the second substrate 7, and the lid 17. For example, the resonator 10 is hermetically sealed in the accommodation space S1 and is desirably in a reduced pressure state which is a state close to vacuum. Thus, the resonator 10 can be suitably protected from impact, dust, heat, moisture, and the like. The circuit device 20 which is a semiconductor chip is accommodated in an accommodation space S2 formed by the first substrate 6 and the third substrate 8. In addition, the external terminals 18 and 19 which are electrode terminals for external connection of the oscillator 4 are formed on a bottom surface of the third substrate 8.

In the accommodation space S1, the resonator 10 is connected to a first electrode terminal and a second electrode terminal which are formed on the upper surface of the first substrate 6 and are not illustrated, by conductive connecting portions CDC1 and CDC2. The conductive connecting portions CDC1 and CDC2 may be realized by, for example, conductive bumps such as metal bumps or may be realized by a conductive adhesive. Specifically, a first electrode pad which is formed at one end of the resonator 10 of a tuning fork type, for example, and is not illustrated is connected to the first electrode terminal formed on the upper surface of the first substrate 6 via the conductive connecting portion CDC1. The first electrode terminal is electrically connected to the pad PX1 of the circuit device 20. Furthermore, a second electrode pad which is formed at the other end of the resonator 10 of the tuning fork type and is not illustrated is connected to the second electrode terminal formed on the upper surface of the first substrate 6 via the conductive connecting portion CDC2. The second electrode terminal is electrically connected to the pad PX2 of the circuit device 20. In this manner, the one end and the other end of the resonator 10 can be electrically connected to the pads PX1 and PX2 of the circuit device 20 via the conductive connecting portions CDC1 and CDC2. In addition, conductive bumps BMP are formed on the plurality of pads of the circuit device 20 which is a semiconductor chip, and the conductive bumps BMP are connected to a plurality of electrode terminals formed on a bottom surface of the first substrate 6. The electrode terminals connected to the pads of the circuit device 20 are electrically connected to the external terminals 18 and 19 of the oscillator 4 via internal wiring and the like.

Note that the oscillator 4 may be a wafer level package (WLP) oscillator. In this case, the oscillator 4 includes a base that includes a semiconductor substrate and a through electrode that passes between a first surface and a second surface of the semiconductor substrate, the resonator 10 that is fixed to the first surface of the semiconductor substrate via a conductive bonding member such as a metal bump, and an external terminal that is provided on the side of the second surface of the semiconductor substrate via an insulating layer such as a relocation wiring layer. Then, an integrated circuit serving as the circuit device 20 is formed on the first surface or the second surface of the semiconductor substrate. In this case, a first semiconductor wafer on which a plurality of bases with the resonators 10 and integrated circuits disposed thereon are formed and a second semiconductor wafer on which a plurality of lids are formed are attached to each other, such that the plurality of bases and the plurality of lids are bonded to each other, and individual pieces of the oscillators 4 are then obtained by a dicing saw or the like. In this manner, it is possible to realize the oscillator 4 of the wafer level package, and it is possible to manufacture the oscillator 4 with a high throughput and at low cost.

As described above, the circuit device of the present embodiment is a circuit device which operates by being supplied with a power supply voltage and includes the oscillation circuit configured to oscillate the resonator, the temperature sensor configured to output the temperature detection voltage, and the offset adjustment circuit configured to output the offset adjustment voltage of the temperature detection voltage. The circuit device includes the correction voltage output circuit configured to receive inputs of the power supply voltage and the offset adjustment voltage and output the correction voltage that changes in accordance with the power supply voltage and the offset adjustment voltage, the correction circuit configured to receive inputs of the temperature detection voltage and the correction voltage and output the temperature detection voltage corrected with the correction voltage, and the temperature compensation circuit configured to perform temperature compensation of the oscillation frequency of the oscillation circuit based on the corrected temperature detection voltage.

According to the present embodiment, the offset adjustment voltage is generated by the offset adjustment circuit, the temperature detection voltage of the temperature sensor is corrected with the correction voltage generated with the power supply voltage and the offset adjustment voltage, and the temperature compensation is performed with the corrected temperature detection voltage. Therefore, it is possible to suppress the problem of degradation of the linearity of the offset adjustment caused by providing the temperature sensor with the offset adjustment function and the like. It is thus possible to provide a circuit device or the like capable of realizing temperature compensation that appropriately reflects influences of a variation in power supply voltage and the offset adjustment.

In the present embodiment, the correction voltage output circuit may include the operational amplifier configured to receive an input of the power supply compensation voltage that changes in accordance with the power supply voltage to the first input terminal and an input of the offset adjustment voltage to the second input terminal and output the correction voltage from the output terminal.

In this manner, the correction voltage that reflects the power supply voltage and the offset adjustment voltage can be output from the output terminal of the operational amplifier.

In the present embodiment, the correction voltage output circuit may include the first resistor and the second resistor provided in series between the input node of the power supply voltage and the node of the output terminal, and the power supply compensation voltage from the connection node between the first resistor and the second resistor may be supplied to the first input terminal of the operational amplifier.

In this manner, the resistor-divided voltage obtained by the first resistor and the second resistor can be input to the first input terminal of the operational amplifier as the power supply compensation voltage.

In the present embodiment, the resistance ratio between the first resistor and the second resistor may be variable, or at least one of the resistance value of the first resistor and the resistance value of the second resistor may be variable.

In this manner, how to reflect each of the power supply voltage and the offset adjustment voltage to the correction voltage can be variably controlled by the resistance ratio or the resistance values of the first resistor and the second resistor.

In the present embodiment, the offset adjustment circuit may be a circuit that D/A converts offset adjustment data into the offset adjustment voltage by the R-2R ladder system.

According to the offset adjustment circuit of the D/A conversion circuit of the R-2R ladder type, it is possible to improve linearity or the like of the offset adjustment as compared with a configuration in which the temperature sensor is caused to have the offset adjustment function.

In the present embodiment, the correction circuit may include the operational amplifier configured to receive an input of the compensation voltage that changes in accordance with the correction voltage to the first input terminal and an input of the temperature detection voltage to the second input terminal and output the corrected temperature detection voltage from the output terminal.

In this manner, the corrected temperature detection voltage obtained by reflecting the correction voltage on the temperature detection voltage of the temperature sensor can be output from the output terminal of the operational amplifier.

In the present embodiment, the correction circuit may include the first resistor and the second resistor provided in series between the input node of the correction voltage and the node of the output terminal, and the compensation voltage from the connection node between the first resistor and the second resistor may be supplied to the first input terminal of the operational amplifier.

In this manner, the resistor-divided voltage obtained by the first resistor and the second resistor can be input to the first input terminal of the operational amplifier as the compensation voltage. Accordingly, the compensation voltage that changes in accordance with the correction voltage is input to the first input terminal of the operational amplifier with the second input terminal to which the temperature detection voltage is input.

In the present embodiment, the correction circuit may change the corrected temperature detection voltage by the amount of change in voltage corresponding to the temperature difference between the temperature detected by the temperature sensor and the temperature of the resonator when the temperature difference changes due to a variation in power supply voltage.

In this manner, since the correction to change the temperature detection voltage by the amount of change in voltage corresponding to the temperature difference between the temperature detected by the temperature sensor and the temperature of the resonator is performed even in a case where the temperature difference changes due to a variation in power supply voltage, it is possible to reduce an error of the temperature compensation due to the temperature difference.

In the present embodiment, the correction voltage output circuit may output the correction voltage that monotonically decreases or monotonically increases in accordance with the rise of the power supply voltage and has a variable amount of change in voltage with respect to a variation in power supply voltage.

In this manner, the temperature compensation is performed using, for correction of the temperature detection by the temperature sensor, the correction voltage which monotonically decreases or monotonically increases when the power supply voltage rises and has a variable amount of change in voltage with respect to a variation in power supply voltage.

Also, the oscillator according to the present embodiment includes the circuit device described above and the resonator.

Although the present embodiment has been described in detail as above, it will be easily understood by those skilled in the art that various modifications could be made without substantially departing from the novel matters and effects of the present disclosure. Therefore, all such modification examples fall within the scope of the present disclosure. For example, a term described at least once together with a different term having a broader meaning or the same meaning in the specification or the drawings can be replaced with the different term anywhere in the specification or the drawings. In addition, all combinations of the present embodiment and modification examples also fall within the scope of the present disclosure. In addition, the configurations, the operations, and the like of the circuit device and the oscillator are also not limited to those described in the present embodiment, and various modifications can be made.

What is claimed is:

1. A circuit device that operates by being supplied with a power supply voltage, comprising:
an oscillation circuit configured to oscillate a resonator;
a temperature sensor configured to output a temperature detection voltage;
an offset adjustment circuit configured to output an offset adjustment voltage of the temperature detection voltage;
a correction voltage output circuit configured to receive inputs of the power supply voltage and the offset adjustment voltage and output a correction voltage that changes in accordance with the power supply voltage and the offset adjustment voltage;
a correction circuit configured to receive inputs of the temperature detection voltage and the correction voltage and output the temperature detection voltage corrected with the correction voltage; and
a temperature compensation circuit configured to perform temperature compensation of an oscillation frequency of the oscillation circuit based on the corrected temperature detection voltage.

2. The circuit device according to claim 1, wherein
the correction voltage output circuit includes
an operational amplifier configured to receive an input of a power supply compensation voltage that changes in accordance with the power supply voltage to a first input terminal and an input of the offset adjustment voltage to a second input terminal and output the correction voltage from an output terminal.

3. The circuit device according to claim 2, wherein
the correction voltage output circuit includes
a first resistor and a second resistor provided in series between an input node of the power supply voltage and a node of the output terminal, and
the power supply compensation voltage from a connection node between the first resistor and the second resistor is supplied to the first input terminal of the operational amplifier.

4. The circuit device according to claim 3, wherein
a resistance ratio between the first resistor and the second resistor is variable, or at least one of a resistance value of the first resistor and a resistance value of the second resistor is variable.

5. The circuit device according to claim 1, wherein
the offset adjustment circuit is
a circuit configured to D/A convert offset adjustment data into the offset adjustment voltage by an R-2R ladder system.

6. The circuit device according to claim 1, wherein
the correction circuit includes
an operational amplifier configured to receive an input of a compensation voltage that changes in accordance with the correction voltage to a first input terminal and an input of the temperature detection voltage to a second input terminal and output the corrected temperature detection voltage from an output terminal.

7. The circuit device according to claim 6, wherein
the correction circuit includes
a first resistor and a second resistor provided in series between an input node of the correction voltage and a node of the output terminal, and
the compensation voltage from a connection node between the first resistor and the second resistor is supplied to the first input terminal of the operational amplifier.

8. The circuit device according to claim 1, wherein
the correction circuit
changes the corrected temperature detection voltage by an amount of change in voltage corresponding to a temperature difference between a temperature detected by the temperature sensor and a temperature of the resonator when the temperature difference changes due to a variation in the power supply voltage.

9. The circuit device according to claim 1, wherein
the correction voltage output circuit
outputs the correction voltage that monotonically decreases or monotonically increases in accordance with a rise of the power supply voltage and has a variable amount of change in voltage with respect to a variation in the power supply voltage.

10. An oscillator comprising:
the circuit device according to claim 1; and
the resonator.
